(19) United States
(12) Patent Application Publication
(10) Pub. No.: US 2016/0138185 A1
(43) Pub. Date: May 19, 2016

(54) METHOD OF MANUFACTURING SILICON CARBIDE SINGLE CRYSTAL

(71) Applicant: SUMITOMO ELECTRIC INDUSTRIES, LTD., Osaka (JP)

(72) Inventors: Tsutomu HORI, Itami-shi (JP); Shin HARADA, Itami-shi (JP)

(21) Appl. No.: 14/877,111

(22) Filed: Oct. 7, 2015

(30) Foreign Application Priority Data
Nov. 18, 2014 (JP) 2014-233756
Dec. 1, 2014 (JP) 2014-243033
Dec. 1, 2014 (JP) 2014-243123

(51) Int. Cl. C30B 23/00; C30B 29/36; C30B 23/06

(52) U.S. Cl. CPC C30B 23/002; C30B 23/066; C30B 29/36

(57) ABSTRACT

A device for manufacturing a silicon carbide single crystal is prepared. The device includes a first resistive heater, a heat insulator, and a chamber. The heat insulator is provided with a first opening in a position facing the first resistive heater. The chamber is provided with a second opening in communication with the first opening. The first resistive heater has a first slit extending from an upper end surface toward a lower end surface of the first resistive heater and a second slit extending from the lower end surface toward the upper end surface, the first and second slits being alternately arranged along a circumferential direction, and the first resistive heater is provided with a third opening penetrating the first resistive heater and being in communication with the first and second openings.

### BACKGROUND OF THE INVENTION

1. Field of the Invention

The present disclosure relates to methods of manufacturing silicon carbide single crystals.

2. Description of the Background Art

In recent years, silicon carbide has been increasingly employed as a material forming a semiconductor device in order to allow for higher breakdown voltage, lower loss and the like of the semiconductor device. Japanese National Patent Publication No. 2012-510951 describes a method of manufacturing a silicon carbide single crystal by sublimation using a crucible made of graphite. Resistive heaters are provided outside the crucible.

### SUMMARY OF THE INVENTION

A method of manufacturing a silicon carbide single crystal according to the present disclosure includes the following steps. A device for manufacturing a silicon carbide single crystal is prepared. The device includes a first resistive heater which is an annular body in which a crucible can be disposed, a heat insulator disposed to surround the circumference of the first resistive heater, and a chamber that accommodates the first resistive heater and the heat insulator, the heat insulator being provided with a first opening in a position facing the first resistive heater, the chamber being provided with a second opening in communication with the first opening, the first resistive heater having a first slit extending from an upper end surface toward a lower end surface of the annular body and a second slit extending from the lower end surface toward the upper end surface, the first and second slits being alternately arranged along a circumferential direction, the first resistive heater being provided with a third opening penetrating the annular body and being in communication with the first and second openings. The device further includes a first pyrometer disposed outside the chamber, the first pyrometer being configured to be able to measure a temperature of the crucible through the first to third openings. A source material and a seed crystal facing the source material are disposed in the crucible. A silicon carbide single crystal grows on the seed crystal by sublimation of the source material.

### BRIEF DESCRIPTION OF THE DRAWINGS

FIG. 1 is a schematic vertical sectional view showing the configuration of a device of manufacturing a silicon carbide single crystal according to an embodiment.

FIG. 2 is a schematic vertical sectional view showing the configuration of the device of manufacturing a silicon carbide single crystal according to the embodiment, with a crucible and pyrometers disposed.

FIG. 3 is a schematic perspective view showing the configuration of a first resistive heater.

FIG. 4 is a schematic plan view showing the configuration of the first resistive heater and terminals.

FIG. 5 is a schematic side view showing the configuration of the first resistive heater and the terminals.

FIG. 6 is a schematic transverse sectional view taken along line VI-VI in a direction of arrows in FIG. 2, which shows the configuration of a third resistive heater and terminals.

FIG. 7 is a schematic transverse sectional view taken along line VII-VII in a direction of arrows in FIG. 2, which shows the configuration of a second resistive heater and terminals.

FIG. 8 is a flowchart showing a method of manufacturing a silicon carbide single crystal according to the embodiment.

FIG. 9 is a schematic vertical sectional view showing a first step of the method of manufacturing a silicon carbide single crystal according to the embodiment.

FIG. 10 is a diagram showing temporal variation in temperature of the crucible.

FIG. 11 is a diagram showing temporal variation in pressure in a chamber.

FIG. 12 is a schematic vertical sectional view showing a second step of the method of manufacturing a silicon carbide single crystal according to the embodiment.

FIG. 13 is a schematic side view showing the configuration of the first resistive heater in a first example of a device of manufacturing a silicon carbide single crystal according to a first variation.

FIG. 14 is a schematic side view showing the configuration of the first resistive heater in a second example of the device of manufacturing a silicon carbide single crystal according to the first variation.

FIG. 15 is a schematic side view showing the configuration of the first resistive heater in a third example of the device of manufacturing a silicon carbide single crystal according to the first variation.

FIG. 16 is a schematic side view showing the configuration of the first resistive heater in a fourth example of the device of manufacturing a silicon carbide single crystal according to the first variation.

FIG. 17 is a schematic plan view showing the configuration of the first resistive heater and the terminals in a first example of a device of manufacturing a silicon carbide single crystal according to a second variation.

FIG. 18 is a schematic side view showing the configuration of the first resistive heater and the terminals in a second example of the device of manufacturing a silicon carbide single crystal according to the second variation.

FIG. 19 is a schematic vertical sectional view showing the configuration of a device of manufacturing a silicon carbide single crystal according to a third variation.

FIG. 20 is a schematic plan view showing the configuration of the first resistive heater and a first power supply according to the third variation.

FIG. 21 is a schematic transverse sectional view taken along line XXI-XXI in a direction of arrows in FIG. 19, which shows the configuration of the second resistive heater and a second power supply.

FIG. 22 is a schematic transverse sectional view taken along line XXII-XXII in a direction of arrows in FIG. 19, which shows the configuration of the third resistive heater and a third power supply.

FIG. 23 is a functional block diagram illustrating temperature control of the crucible in the device of manufacturing a silicon carbide single crystal according to the third variation.

FIG. 24 is a flowchart showing a method of manufacturing a silicon carbide single crystal according to the third variation.

FIG. 25 is a schematic vertical sectional view showing a first step of the method of manufacturing a silicon carbide single crystal according to the third variation.

FIG. 26 is a diagram showing temporal variation in temperature of the crucible and pressure in the chamber.

FIG. 27 is a diagram showing temporal variation in power supplied to the second resistive heater, temperature of a top surface measured by an upper pyrometer, and pressure in the chamber.

FIG. 28 is a flowchart showing a control process procedure for implementing switching of control of the second resistive heater.

FIG. 29 is a schematic vertical sectional view showing a second step of the method of manufacturing a silicon carbide single crystal according to the third variation.

FIG. 30 is a schematic vertical sectional view showing the configuration of a device of manufacturing a silicon carbide single crystal according to a sixth variation.

FIG. 31 is a functional block diagram illustrating temperature control of the crucible in the device of manufacturing a silicon carbide single crystal according to the sixth variation.

FIG. 32 is a schematic vertical sectional view showing the configuration of a device of manufacturing a silicon carbide single crystal according to a seventh variation.

FIG. 33 is a functional block diagram illustrating temperature control of the crucible in the device of manufacturing a silicon carbide single crystal according to the seventh variation.

FIG. 34 is a functional block diagram illustrating temperature control of the crucible in a device of manufacturing a silicon carbide single crystal according to an eighth variation.

FIG. 35 is a diagram showing temporal variation in power supplied to the second resistive heater, temperature of the top surface measured by the upper pyrometer, and pressure in the chamber.

FIG. 36 is a flowchart showing a control process procedure for implementing switching of control of the second resistive heater.

FIG. 37 is a functional block diagram illustrating temperature control of the crucible in a device of manufacturing a silicon carbide single crystal according to an eleventh variation.

### DETAILED DESCRIPTION OF THE INVENTION

### Description of Embodiments

An object of one embodiment of the present disclosure is to provide a device of manufacturing a silicon carbide single crystal capable of directly measuring the temperature of a crucible during crystal growth.

Some of manufacturing devices of manufacturing silicon carbide single crystals by sublimation include a resistive heater as a heating unit for heating a crucible in order to cause sublimation of a silicon carbide source material disposed in the crucible and recrystallization of the source material on a seed crystal. Such a manufacturing device usually includes, in a chamber forming the outline of the device, the resistive heater disposed to cover an outer surface of the crucible, and a heat insulator disposed to surround the circumferences of the crucible and the resistive heater. The temperature of each of the silicon carbide source material and the seed crystal is adjusted by controlling an amount of heat generated by the resistive heater by means of power supplied to the resistive heater. Consequently, a temperature gradient required for the sublimation and recrystallization is formed between the silicon carbide source material and the seed crystal.

In order to control the temperature gradient, a pyrometer for measuring the temperature of the resistive heater is provided outside the chamber in a position facing the resistive heater. Each of the chamber and the heat insulator is provided with an opening such that a surface of the resistive heater is partially exposed at the chamber. The pyrometer can measure the temperature of the resistive heater through these openings.

Unfortunately, since the resistive heater is made of a material including graphite, the resistive heater may partially sublimate and gradually change in shape as a result of repeated growth of a silicon carbide single crystal using the same resistive heater. The change in shape of the resistive heater causes a change in amount of heat transferred from the resistive heater to the crucible. Thus, even if the temperature of the resistive heater measured by the pyrometer is the same before and after the change in shape of the resistive heater, the temperature of the crucible may not necessarily be the same. When the heat conductivity between the resistive heater and the crucible varies due to the change in shape of the resistive heater in this manner, it is difficult to control the above-described temperature gradient. This may result in lowered crystal quality of the silicon carbide single crystal.

(1) A method of manufacturing a silicon carbide single crystal according to the present disclosure includes the following steps. A device for manufacturing a silicon carbide single crystal is prepared. The device includes a first resistive heater which is an annular body in which a crucible can be disposed, a heat insulator disposed to surround the circumference of the first resistive heater, and a chamber that accommodates the first resistive heater and the heat insulator, the heat insulator being provided with a first opening in a position facing the first resistive heater, the chamber being provided with a second opening in communication with the first opening, the first resistive heater having a first slit extending from an upper end surface toward a lower end surface of the annular body and a second slit extending from the lower end surface toward the upper end surface, the first and second slits being alternately arranged along a circumferential direction, the first resistive heater being provided with a third opening penetrating the annular body and being in communication with the first and second openings. The device further includes a first pyrometer disposed outside the chamber, the first pyrometer being configured to be able to measure a temperature of the crucible through the first to third openings. A source material and a seed crystal facing the source material are disposed in the crucible. A silicon carbide single crystal grows on the seed crystal by sublimation of the source material.

In accordance with the method of manufacturing a silicon carbide single crystal according to (1) above, the first resistive heater is provided with the third opening in communication with the first opening provided in the heat insulator and the second opening provided in the chamber. Thus, an outer surface of the crucible can be partially exposed to the outside of the chamber through the first to third openings. Accordingly, the temperature of the crucible can be directly measured through the first to third openings, with the first pyrometer disposed outside the chamber in a position facing the outer surface of the crucible. As a result, a temperature gradient in the crucible during crystal growth can be controlled without being affected by a change in shape of the first resistive heater.

(2) In the method of manufacturing a silicon carbide single crystal according to (1) above, the third opening may have a line-symmetrical shape with an axis passing through the first slit or the second slit as a symmetry axis. According to this method, the occurrence of a difference in resistance value of the first resistive heater between opposing portions surrounding the third opening can be avoided, thereby preventing the third opening from creating an imbalance in the amount of heat generation in the annular body.

(3) In the method of manufacturing a silicon carbide single crystal according to (1) above, the device may further include a first terminal having one end electrically connected to one pole of a power supply and the other end connected to the upper end surface or the lower end surface, and a second terminal having one end electrically connected to the other pole of the power supply and the other end connected to the upper end surface or the lower end surface. The first terminal and the second terminal may be disposed in positions facing each other with a central axis of the annular body therebetween. The third opening may be disposed in a position at least partially overlapping with the other end of the first terminal or the second terminal when viewed from the upper end surface. According to this method, the occurrence of a difference in resistance value between a pair of resistive elements connected in parallel between the first terminal and the second terminal can be prevented on an equivalent circuit formed of the resistive elements. Thus, a balance in the amount of heat generation can be maintained between the pair of resistive elements, thereby preventing the third opening from creating an imbalance in the amount of heat generation in the first resistive heater.

A manufacturing device of manufacturing a silicon carbide single crystal by sublimation is provided with a heating unit for heating a crucible in order to cause sublimation of a silicon carbide source material disposed in the crucible and recrystallization of the source material on a seed crystal. In such a manufacturing device, usually, the temperature of each of the silicon carbide source material and the seed crystal is adjusted by controlling an amount of heat generated by the heating unit by means of power supplied to the heating unit, with a heat insulator disposed to surround the circumference of the crucible in a chamber forming the outline of the device. Consequently, a temperature gradient required for the sublimation and recrystallization is formed between the silicon carbide source material and the seed crystal.

In order to control the temperature gradient, a pyrometer for measuring the temperature of the crucible is provided outside the chamber in a position facing an outer surface of the crucible. Each of the chamber and the heat insulator is provided with an opening for temperature measurement such that the outer surface of the crucible is partially exposed at the chamber. The pyrometer is configured to be able to measure the temperature of the crucible through these openings.

During silicon carbide single crystal growth, the interior of the crucible has a high temperature in order to sublimate silicon carbide, whereas the exterior of the crucible has a temperature lower than that of the interior. A source material gas may be diffused to the outside of the crucible through a gap which is formed, for example, in a portion where a cover portion holding the seed crystal and an accommodation unit accommodating the silicon carbide source material are joined to each other. In the heat insulator covering the circumference of the crucible, therefore, the source material gas may recrystallize in a portion having a temperature at which silicon carbide recrystallizes. In particular, if the source material gas recrystallizes near an opening, silicon carbide adheres to an inner wall surface of the opening. As the amount of adhesion of silicon carbide increases, the opening is gradually blocked, resulting in difficulty in accurately measuring the temperature of the crucible through the opening. This leads to difficulty in controlling the temperature of the crucible, which may cause the temperature control during crystal growth to become unstable. As a result, temperature variation in the crucible occurs, which may cause cracks and the like in the silicon carbide single crystal.

(4) In the method of manufacturing a silicon carbide single crystal according to (1) above, the step of growing a silicon carbide single crystal on the seed crystal by sublimation of the source material may be performed by supplying power to the first resistive heater to heat the crucible. The step of growing a silicon carbide single crystal may include a first step in which the power supplied to the first resistive heater is feedback controlled based on the temperature of the crucible measured by the first pyrometer, and a second step in which the power supplied to the first resistive heater is controlled to be constant power. The power supplied to the first resistive heater in the second step may be determined by calculation based on the power supplied to the first resistive heater in the first step.

In the method of manufacturing a silicon carbide single crystal according to (4) above, the control of the power supplied to the first resistive heater in the step of growing a silicon carbide single crystal is the feedback control based on a difference between a measured value of the temperature of the crucible and a target value, then switched to the constant power control where the power is fixed to constant power. The power supplied to the heater during the constant power control is determined by calculation from the power feedback controlled in the first step. Consequently, also in the second step in which the constant power control is performed, the first resistive heater can generate an amount of heat for silicon carbide single crystal growth. As a result, during the silicon carbide single crystal growth, even when the first opening for temperature measurement is blocked due to the recrystallized silicon carbide, the temperature control of the crucible can be prevented from becoming unstable.

(5) In the method of manufacturing a silicon carbide single crystal according to (4) above, the crucible may have a top surface, a bottom surface opposite to the top surface, and a tubular side surface located between the top surface and the bottom surface. The device may further include a second resistive heater provided to face the top surface, and a third resistive heater provided to face the bottom surface. The first resistive heater may be provided to surround the side surface. The heat insulator may be disposed to cover the first resistive heater, the second resistive heater and the third resistive heater. The heat insulator may be provided with a fourth opening in each of a position facing the top surface and a position facing the bottom surface. The device may further include a second pyrometer configured to be able to measure a temperature of the top surface through the fourth opening, and a third pyrometer configured to be able to measure a temperature of the bottom surface through the fourth opening. In the first step, the powers supplied to the first resistive heater, the second resistive heater and the third resistive heater, respectively, may be feedback controlled based on the temperatures of the crucible measured by the first pyrometer, the second pyrometer and the third pyrometer, respectively. In the second step, the powers supplied to the first resistive heater and the third resistive heater, respectively, may be feedback controlled based on the temperatures of the crucible measured by the first pyrometer and the third pyrometer, respectively, and the power supplied to the second resistive heater may be controlled to be constant power. The power supplied to the second resistive heater in the second step may be determined by calculation based on the power supplied to the second resistive heater in the first step.

During the silicon carbide single crystal growth, the temperature of the crucible decreases in a direction from the bottom surface toward the top surface, and therefore, the source material gas diffused to the outside of the crucible is transferred in the direction toward the top surface in accordance with this temperature gradient. Thus, the source material gas tends to recrystallize near the opening for temperature measurement disposed to face the top surface. According to this embodiment, even when the fourth opening for temperature measurement disposed to face the top surface is blocked, the second resistive heater can generate an amount of heat for maintaining the temperature of the top surface at a target value, thereby preventing the temperature control of the crucible during the silicon carbide single crystal growth from becoming unstable.

(6) In the method of manufacturing a silicon carbide single crystal according to (4) above, the crucible may have a top surface, a bottom surface opposite to the top surface, and a tubular side surface located between the top surface and the bottom surface. The device may further include a second resistive heater provided to face the top surface, and a third resistive heater provided to face the bottom surface. The first resistive heater may be provided to surround the side surface. The heat insulator may be disposed to cover the first resistive heater, the second resistive heater and the third resistive heater. The heat insulator may be provided with a fourth opening in each of a position facing the top surface and a position facing the bottom surface. The device may include a second pyrometer configured to be able to measure a temperature of the top surface through the fourth opening, and a third pyrometer configured to be able to measure a temperature of the bottom surface through the fourth opening. In the first step, the powers supplied to the first resistive heater, the second resistive heater and the third resistive heater, respectively, may be feedback controlled based on the temperatures of the crucible measured by the first pyrometer, the second pyrometer and the third pyrometer, respectively. In the second step, the powers supplied to the second resistive heater and the third resistive heater, respectively, may be feedback controlled based on the temperatures of the crucible measured by the second pyrometer and the third pyrometer, respectively, and the power supplied to the first resistive heater may be controlled to be constant power.

While the source material gas diffused to the outside of the crucible is transferred in the direction toward the top surface, the source material gas may recrystallize also near the first opening for temperature measurement disposed to face the side surface. In accordance with the method of manufacturing a silicon carbide single crystal according to (6) above, even when the first opening for temperature measurement disposed to face the side surface is blocked, the first resistive heater can generate an amount of heat for maintaining the temperature of the side surface at a target value, thereby preventing the temperature control of the crucible during the silicon carbide single crystal growth from becoming unstable.

(7) In the method of manufacturing a silicon carbide single crystal according to (4) above, in the step of growing a silicon carbide single crystal, pressure reduction in the crucible may be carried out during execution of the first step. The power supplied to the first resistive heater in the second step may be determined by calculation based on the power supplied to the first resistive heater in the first step after completion of the pressure reduction in the crucible. Consequently, the power supplied to the first resistive heater during the constant power control is determined by calculation from the power feedback controlled during a period when the silicon carbide single crystal grows on the surface of the seed crystal. Thus, the first resistive heater can generate an amount of heat for silicon carbide single crystal growth also during a period when the constant power control is performed, thereby preventing the temperature control of the crucible during the silicon carbide single crystal growth from becoming unstable.

During silicon carbide single crystal growth, the source material gas may be diffused to the outside of the crucible through a gap which is formed, for example, in a portion where a cover portion holding the seed crystal and an accommodation unit accommodating the silicon carbide source material are joined to each other. Since the temperature of the crucible decreases in a direction from the bottom surface toward the top surface, the source material gas diffused to the outside of the crucible is transferred in the direction toward the top surface in accordance with this temperature gradient. In the heat insulator covering the crucible, therefore, the source material gas may recrystallize in a portion facing the top surface. In particular, if the source material gas recrystallizes near an opening disposed to face the top surface, silicon carbide adheres to an inner wall surface of the opening. As the amount of adhesion of silicon carbide increases, the opening is gradually blocked, resulting in difficulty in accurately measuring the temperature of the crucible through the opening. This leads to difficulty in controlling the temperature of the crucible, which may cause the temperature control during crystal growth to become unstable. As a result, temperature variation in the crucible occurs, which may cause cracks and the like in the silicon carbide single crystal.

(8) In the method of manufacturing a silicon carbide single crystal according to (1) above, the crucible may have a top surface, a bottom surface opposite to the top surface, and a tubular side surface located between the top surface and the bottom surface. The source material may be disposed in the crucible on the side close to the bottom surface. The seed crystal may be disposed in the crucible on the side close to the top surface so as to face the source material. The device may include a second resistive heater for heating the top surface, and a third resistive heater for heating the bottom surface. The heat insulator may be disposed to cover the crucible. The heat insulator may be provided with a fourth opening in each of at least a position facing the top surface and a position facing the bottom surface. The device may include a second pyrometer configured to be able to measure a temperature of the top surface through the fourth opening, and a third pyrometer configured to be able to measure a temperature of the bottom surface through the fourth opening. The step of growing a silicon carbide single crystal on the seed crystal by sublimation of the source material may be performed by supplying power to each of the first resistive heater, the second resistive heater and the third resistive heater to heat the crucible. The step of growing a silicon carbide single crystal may include a first step in which the powers supplied to the first resistive heater, the second resistive heater and the third resistive heater, respectively, are feedback controlled based on the temperatures of the crucible measured by the first pyrometer, the second pyrometer and the third pyrometer, respectively, and a second step in which the power supplied to the first resistive heater or the third resistive heater is feedback controlled based on the temperature of the crucible measured by the first pyrometer or the third pyrometer, and the power supplied to the second resistive heater is controlled to be associated with the power supplied to the first resistive heater or the third resistive heater. The power supplied to the second resistive heater in the second step may be determined by calculation based on a ratio between the power supplied to the second resistive heater and the power supplied to the first resistive heater or the third resistive heater in the first step, and the power supplied to the first resistive heater or the third resistive heater in the second step.

In the method of manufacturing a silicon carbide single crystal according to (8) above, in the step of growing a silicon carbide single crystal, the control of the power supplied to the second resistive heater is the feedback control based on a difference between a measured value of the temperature of the top surface and a target value, then switched to the associated control where the power supplied to the second resistive heater is associated with the power supplied to the first resistive heater or the third resistive heater. Consequently, complete feedback control where the powers supplied to the first resistive heater, the second resistive heater and the third resistive heater are feedback controlled is switched to partial feedback control where only the powers supplied to the first resistive heater and the third resistive heater are feedback controlled. The power supplied to the second resistive heater during this partial feedback control is controlled such that a ratio between the power supplied to the second resistive heater and the power supplied to the first resistive heater or the third resistive heater during the complete feedback control is maintained relative to the power supplied to the first resistive heater or the third resistive heater. Thus, the second resistive heater can generate an amount of heat for maintaining the temperature of the top surface at the target value also during a period when the partial feedback control is performed. As a result, during the silicon carbide single crystal growth, even when the fourth opening for temperature measurement disposed to face the top surface is blocked due to the recrystallized silicon carbide, the temperature control of the crucible can be prevented from becoming unstable.

(9) In the method of manufacturing a silicon carbide single crystal according to (8) above, the heat insulator may be disposed to cover the first resistive heater, the second resistive heater and the third resistive heater. In the second step, the powers supplied to the first resistive heater and the third resistive heater, respectively, may be feedback controlled based on the temperatures of the crucible measured by the first pyrometer and the third pyrometer, respectively, and the power supplied to the second resistive heater may be controlled to be associated with the power supplied to the first resistive heater. The power supplied to the second resistive heater in the second step may be determined by calculation based on a ratio between the power supplied to the second resistive heater and the power supplied to the first resistive heater in the first step, and the power supplied to the first resistive heater in the second step.

In accordance with the method of manufacturing a silicon carbide single crystal according to (9) above, during the partial feedback control, the power supplied to the second resistive heater is controlled such that a ratio between the power supplied to the second resistive heater and the power supplied to the first resistive heater during the complete feedback control is maintained relative to the power supplied to the first resistive heater. Thus, even when the fourth opening for temperature measurement disposed to face the top surface is blocked, the second resistive heater can generate an amount of heat for maintaining the temperature of the top surface at the target value, thereby preventing the temperature control of the crucible during the silicon carbide single crystal growth from becoming unstable.

(10) In the method of manufacturing a silicon carbide single crystal according to (8) above, the heat insulator may be disposed to cover the first resistive heater, the second resistive heater and the third resistive heater. In the second step, the powers supplied to the first resistive heater and the third resistive heater, respectively, may be feedback controlled based on the temperatures of the crucible measured by the first pyrometer and the third pyrometer, respectively, and the power supplied to the second resistive heater may be controlled to be associated with the power supplied to the third resistive heater. The power supplied to the second resistive heater in the second step may be determined by calculation based on a ratio between the power supplied to the second resistive heater and the power supplied to the third resistive heater in the first step, and the power supplied to the third resistive heater in the second step.

In accordance with the method of manufacturing a silicon carbide single crystal according to (10) above, during the partial feedback control, the power supplied to the second resistive heater is controlled such that a ratio between the power supplied to the second resistive heater and the power supplied to the third resistive heater during the complete feedback control is maintained relative to the power supplied to the third resistive heater. Thus, even when the fourth opening for temperature measurement disposed to face the top surface is blocked, the second resistive heater can generate an amount of heat for maintaining the temperature of the top surface at the target value, thereby preventing the temperature control of the crucible during the silicon carbide single crystal growth from becoming unstable.

(11) In the method of manufacturing a silicon carbide single crystal according to (8) above, in the step of growing a silicon carbide single crystal, pressure reduction in the crucible may be carried out during execution of the first step. The power supplied to the second resistive heater in the second step may be determined by calculation based on a ratio between the power supplied to the second resistive heater and the power supplied to the first resistive heater or the third resistive heater in the first step after completion of the pressure reduction in the crucible, and the power supplied to the first resistive heater or the third resistive heater in the second step. Consequently, the ratio between the power supplied to the second resistive heater and the power supplied to the first resistive heater or the third resistive heater during the partial feedback control is determined by calculation from the power feedback controlled during a period when the silicon carbide single crystal grows on the surface of the seed crystal. Thus, the second resistive heater can generate an amount of heat for silicon carbide single crystal growth also during a period when the associated control is performed, thereby preventing the temperature control of the crucible during the silicon carbide single crystal growth from becoming unstable.

### Details of Embodiments

Embodiments will be described below with reference to the drawings. In the following drawings, the same or corresponding parts are designated by the same reference signs and description thereof will not be repeated. An individual plane and a group plane are herein shown in ( ) and { }, respectively. Although a crystallographically negative index is normally expressed by a number with a bar “−” thereabove, a negative sign herein precedes a number to indicate a crystallographically negative index.

<Configuration of Device of Manufacturing Silicon Carbide Single Crystal>

First, the configuration of a device 100 of manufacturing a silicon carbide single crystal according to an embodiment is described.

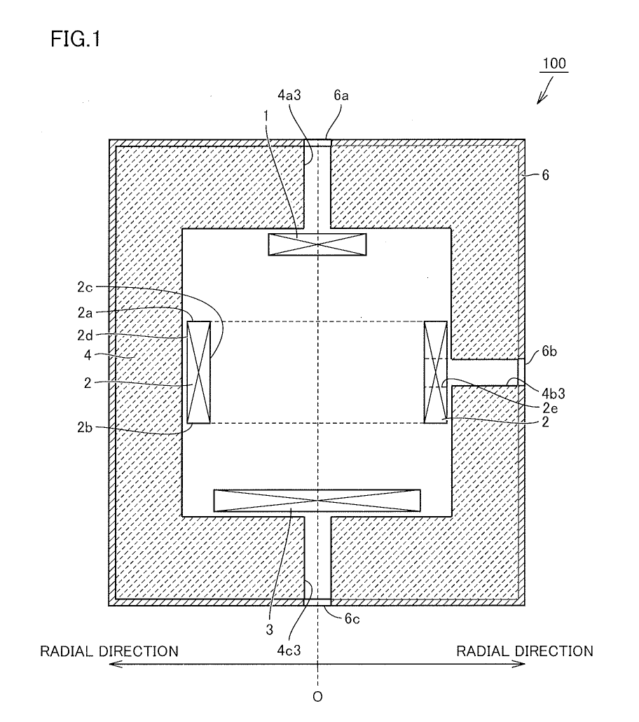

As shown in FIG. 1, device 100 of manufacturing a silicon carbide single crystal according to the embodiment is a device for manufacturing a silicon carbide single crystal by sublimation, and mainly includes a chamber 6, a heat insulator 4, a lateral resistive heater 2 (first resistive heater), an upper resistive heater 1 (second resistive heater), and a lower resistive heater 3 (third resistive heater).

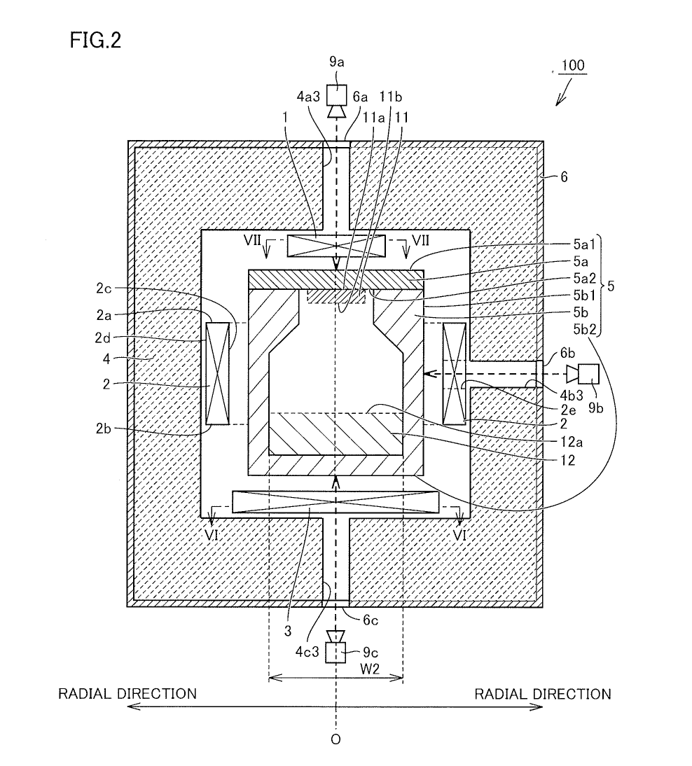

Heat insulator 4 is configured to be able to accommodate a crucible 5, upper resistive heater 1, lateral resistive heater 2 and lower resistive heater 3 (see FIG. 2). Heat insulator 4 is, for example, graphite, a graphite felt, a molded heat insulator made of carbon, a molded heat insulator made of graphite, or a graphite sheet. Heat insulator 4 may be a combination of two or more of graphite, a graphite felt, a molded heat insulator made of carbon and a graphite sheet. The molded heat insulator means, for example, graphite felts which are stacked, bonded together with an adhesive, and then sintered. As shown in FIG. 2, heat insulator 4 is provided to surround the circumference of crucible 5 when crucible 5 is disposed in chamber 6. As shown in FIG. 2, manufacturing device 100 further includes crucible 5, a lateral pyrometer 9b (first pyrometer), an upper pyrometer 9a (second pyrometer), and a lower pyrometer 9c (third pyrometer).

Crucible 5 is made of graphite, for example, and has a top surface 5a1, a bottom surface 5b2 opposite to top surface 5a1, and a tubular side surface 5b1 located between top surface 5a1 and bottom surface 5b2. Side surface 5b1 has a cylindrical shape, for example. Crucible 5 has a pedestal 5a configured to be able to hold a seed crystal 11, and an accommodation unit 5b configured to be able to accommodate a silicon carbide source material 12. Pedestal 5a has a seed crystal holding surface 5a2 in contact with a backside surface 11a of seed crystal 11, and top surface 5a1 opposite to seed crystal holding surface 5a2. Pedestal 5a forms top surface 5a1. Accommodation unit 5b forms bottom surface 5b2. Side surface 5b1 is formed of pedestal 5a and accommodation unit 5b. In crucible 5, a silicon carbide single crystal grows on a surface 11b of seed crystal 11 by sublimation of silicon carbide source material 12 and recrystallization of the source material on surface 11b of seed crystal 11. That is, a silicon carbide single crystal is configured such that it can be manufactured by sublimation.

Upper resistive heater 1, lateral resistive heater 2 and lower resistive heater 3 are disposed outside crucible 5, and form a heating unit for heating crucible 5. If a resistance heating heater is used for the heating unit, the heating unit is preferably disposed between crucible 5 and heat insulator 4 as shown in FIG. 2. Upper resistive heater 1, lateral resistive heater 2 and lower resistive heater 3 may be configured such that amounts of heat generated by theses heaters can be controlled independently of one another. In other words, the heating unit may be configured to be able to adjust temperatures of top surface 5a1, side surface 5b1 and bottom surface 5b2 independently of one another.

Lower resistive heater 3 is provided to face bottom surface 5b2. Lower resistive heater 3 is separated from bottom surface 5b2. Lateral resistive heater 2 is which is an annular body disposed to surround side surface 5b1. Lateral resistive heater 2 is separated from side surface 5b1. Upper resistive heater 1 is provided to face top surface 5a1. Upper resistive heater 1 is separated from top surface 5a1.

Heat insulator 4 is provided with an opening 4c3 (fourth opening) such that lower resistive heater 3 is partially exposed at heat insulator 4. Chamber 6 is provided with an opening 6c in communication with opening 4c3. Heat insulator 4 is provided with an opening 4b3 (first opening) such that lateral resistive heater 2 is partially exposed at heat insulator 4. Chamber 6 is provided with an opening 6b (second opening) in communication with opening 4b3. Heat insulator 4 is provided with an opening 4a3 (fourth opening) such that upper resistive heater 1 is partially exposed at heat insulator 4. Chamber 6 is provided with an opening 6a in communication with opening 4a3. Openings 6a, 6b and 6c are view ports, for example.

Lateral resistive heater 2 includes, in a direction from bottom surface 5b2 toward top surface 5a1, a first surface 2a (upper end surface) located on the side close to top surface 5a1, a second surface 2b (lower end surface) located on the side close to bottom surface 5b2, a third surface 2c facing side surface 5b1, and a fourth surface 2d opposite to third surface 2c.

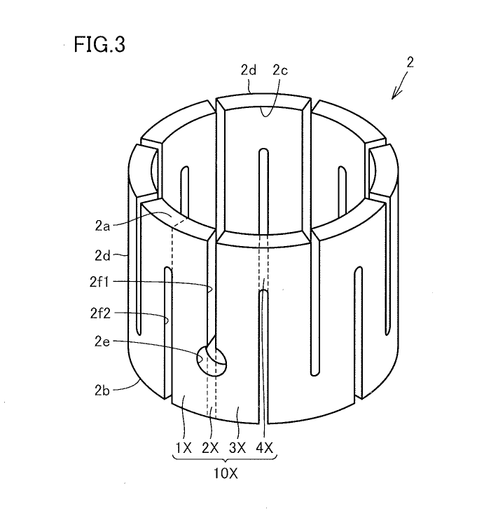

As shown in FIG. 3, lateral resistive heater 2 has a first portion 1x extending along a direction from top surface 5a1 toward bottom surface 5b2, a second portion 2x provided continuously with first portion 1x on the side close to bottom surface 5b2 and extending along a circumferential direction of side surface 5b1, a third portion 3x provided continuously with second portion 2x and extending along the direction from bottom surface 5b2 toward top surface 5a1, and a fourth portion 4x provided continuously with third portion 3x on the side close to top surface 5a1 and extending along the circumferential direction of side surface 5b1. First portion 1x, second portion 2x, third portion 3x and fourth portion 4x form a heater unit 10x. Lateral resistive heater 2 constitutes an annular body formed of a plurality of successively provided heater units 10x.

In each heater unit 10x, a first slit 2f1 extending from first surface 2a toward second surface 2b is formed between first portion 1x and third portion 3x adjacent to each other with second portion 2x interposed therebetween. Further, a second slit 2f2 extending from second surface 2b toward first surface 2a is formed between third portion 3x and first portion 1x adjacent to each other with fourth portion 4x interposed therebetween. Consequently, first slit 2f1 and second slit 2f2 are alternately arranged in the annular body along the circumferential direction.

As shown in FIG. 3, one of the plurality of heater units 10x is provided with an opening 2e (third opening) continuous with first slit 2f1 on the side close to second surface 2b. Opening 2e penetrates the annular body in a direction from third surface 2c toward fourth surface 2d. Opening 2e is in communication with opening 4b3 and opening 6b, as shown in FIGS. 1 and 2.

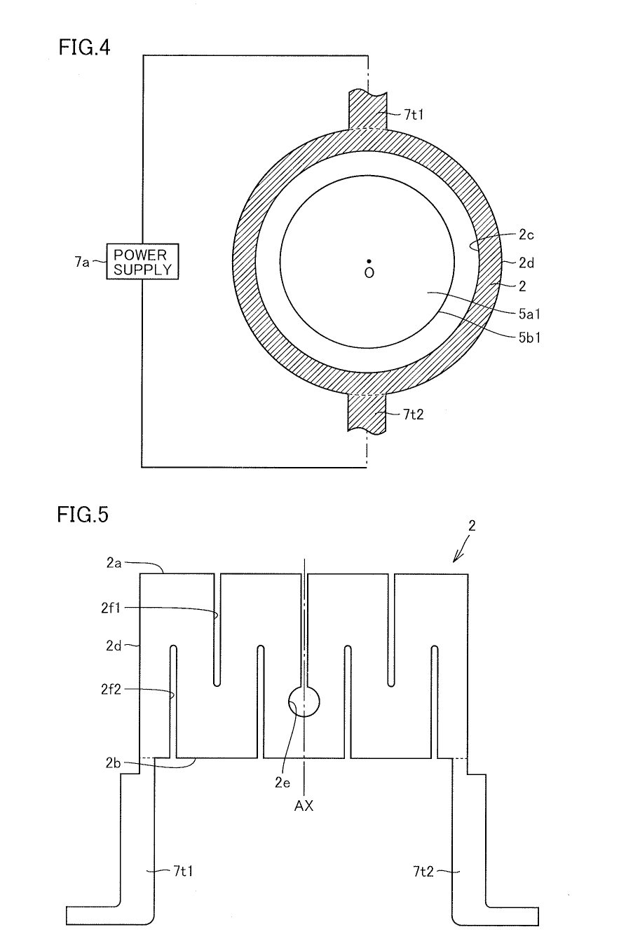

As shown in FIG. 4, when viewed along the direction from top surface 5a1 toward bottom surface 5b2, lateral resistive heater 2 is provided to surround side surface 5b1 of crucible 5, and is formed in an annular shape. A pair of terminals 7t1 and 7t2 is provided in contact with second surface 2b of second resistive heater 2. First terminal 7t1 has one end electrically connected to one pole of a first power supply 7a, and the other end connected to second surface 2b. Second terminal 7t2 has one end electrically connected to the other pole of first power supply 7a, and the other end connected to second surface 2b. The pair of terminals 7t1 and 7t2 may be provided in contact with first surface 2a.

First power supply 7a is configured to be able to supply power to lateral resistive heater 2 through the pair of terminals 711 and 7t2. Lateral resistive heater 2 is represented by an equivalent circuit formed of a pair of resistive elements connected in parallel to first power supply 7a. That is, lateral resistive heater 2 is connected in parallel between the pair of terminals 7t1 and 7t2. First terminal 7t1 and second terminal 7t2 are provided in positions facing each other with a central axis O of the annular body therebetween. Consequently, the pair of resistive elements has the same resistance value on the equivalent circuit, so that the amounts of heat generation can be balanced between the resistive elements.

As shown in FIG. 5, when viewed from fourth surface 2d, opening 2e has a line-symmetrical shape with an axis AX passing through first slit 2f1 as a symmetry axis. In this embodiment, for example, opening 2e has a round shape centered on axis AX. If opening 2e is disposed asymmetrically with respect to axis AX, a difference in resistance value occurs between first portion 1x and third portion 3x surrounding opening 2e, which may result in an imbalance in the amount of heat generation. In order to reduce the difference in resistance value between these two portions, it is preferable to dispose opening 2e in a line-symmetrical manner with respect to axis AX.

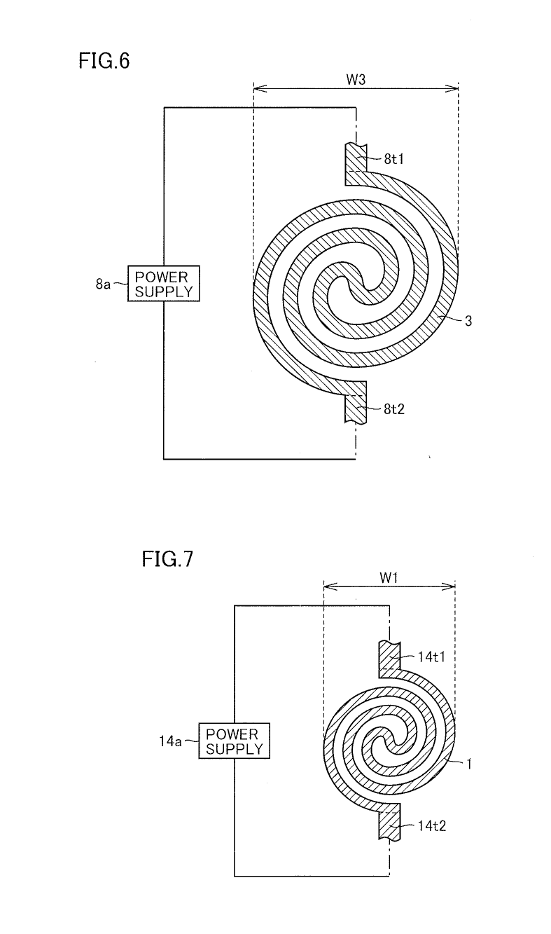

As shown in FIG. 6, when viewed along the direction from top surface 5a1 toward bottom surface 5b2, lower resistive heater 3 has a shape made of two curves which move away from a center while whirling and meet each other at the center. Preferably, lower resistive heater 3 has the shape of a Fermat's spiral. A pair of terminals 8t1 and 8t2 is connected to opposing ends of lower resistive heater 3. Third terminal 8t has one end electrically connected to one pole of a third power supply 8a, and the other end connected to lower resistive heater 3. Fourth terminal 8t2 has one end electrically connected to the other pole of third power supply 8a, and the other end connected to lower resistive heater 3. Third power supply 8a is configured to be able to supply power to lower resistive heater 3 through the pair of terminals 8t1 and 8t2. When viewed along a direction parallel to bottom surface 5b2, a width W3 of lower resistive heater 3 is greater than a width W2 of the interior of crucible 5 (see FIG. 2), and preferably greater than a width of bottom surface 5b2. Width W3 of lower resistive heater 3 is measured exclusive of the pair of terminals 8t1 and 8t2.

As shown in FIG. 7, when viewed along the direction from top surface 5a1 toward bottom surface 5b2, upper resistive heater 1 has a shape made of two curves which move away from a center while whirling and meet each other at the center. Preferably, upper resistive heater 1 has the shape of a Fermat's spiral. A pair of terminals 14t1 and 14t2 is connected to opposing ends of upper resistive heater 1. Fifth terminal 14t1 has one end electrically connected to one pole of a second power supply 14a, and the other end connected to upper resistive heater 1. Sixth terminal 14t2 has one end electrically connected to the other pole of second power supply 14a, and the other end connected to upper resistive heater 1. Second power supply 14a is configured to be able to supply power to upper resistive heater 1 through the pair of terminals 14t1 and 14t2. When viewed along a direction parallel to top surface 5a1, a width W1 of upper resistive heater 1 is smaller than a width of top surface 5a1. Width W1 of upper resistive heater 1 is measured exclusive of the pair of terminals 14t and 14t2.

As shown in FIG. 2, lower pyrometer 9c is provided outside chamber 6 in a position facing bottom surface 5b2 of crucible 5, and configured to be able to measure a temperature of bottom surface 5b2 through opening 4c3, opening 6c, and an opening formed in the vicinity of a center of lower resistive heater 3. The “opening formed in the vicinity of a center of lower resistive heater 3” is realized by an opening formed on opposing sides of a portion where the two curves shown in FIG. 6 meet each other, in the vicinity of a center of the meeting portion.

Lateral pyrometer 9b is provided outside chamber 6 in a position facing side surface 5b1 of crucible 5, and configured to be able to measure a temperature of side surface 5b1 through opening 4b3, opening 6b and opening 2e. Upper pyrometer 9a is provided outside chamber 6 in a position facing top surface 5a1 of crucible 5, and configured to be able to measure a temperature of top surface 5a1 through opening 4a3, opening 6a, and an opening formed in the vicinity of a center of upper resistive heater 1. The “opening formed in the vicinity of a center of upper resistive heater 1” is realized by an opening formed on opposing sides of a portion where the two curves shown in FIG. 7 meet each other, in the vicinity of a center of the meeting portion.

A pyrometer manufactured by CHINO Corporation (model number: IR-CAH8TN6) can be used, for example, as pyrometers 9a to 9c. The pyrometer has measurement wavelengths of 1.55 μm and 0.9 μm, for example. The pyrometer has a set value for emissivity of 0.9, for example. The pyrometer has a distance coefficient of 300, for example. A measurement diameter of the pyrometer is determined by dividing a measurement distance by the distance coefficient. If the measurement distance is 900 mm, for example, the measurement diameter is 3 mm.

The diameter of each of opening 4c3 and opening 6c provided in a position facing lower pyrometer 9c is greater than the measurement diameter of the pyrometer, and is, for example, about 5 to 30 mm. A minimum opening width of the opening formed in the vicinity of the center of lower resistive heater 3 is greater than the measurement diameter of the pyrometer, and is, for example, about 5 mm.

The diameter of each of opening 4b3, opening 6b and opening 2e provided in a position facing lateral pyrometer 9b is greater than the measurement diameter of the pyrometer, and is, for example, about 5 to 30 mm. The diameter of each of opening 4a3 and opening 6a provided in a position facing upper pyrometer 9a is greater than the measurement diameter of the pyrometer, and is, for example, about 5 to 30 mm. A minimum opening width of the opening formed in the vicinity of the center of upper resistive heater 1 is greater than the measurement diameter of the pyrometer, and is, for example, about 5 mm.

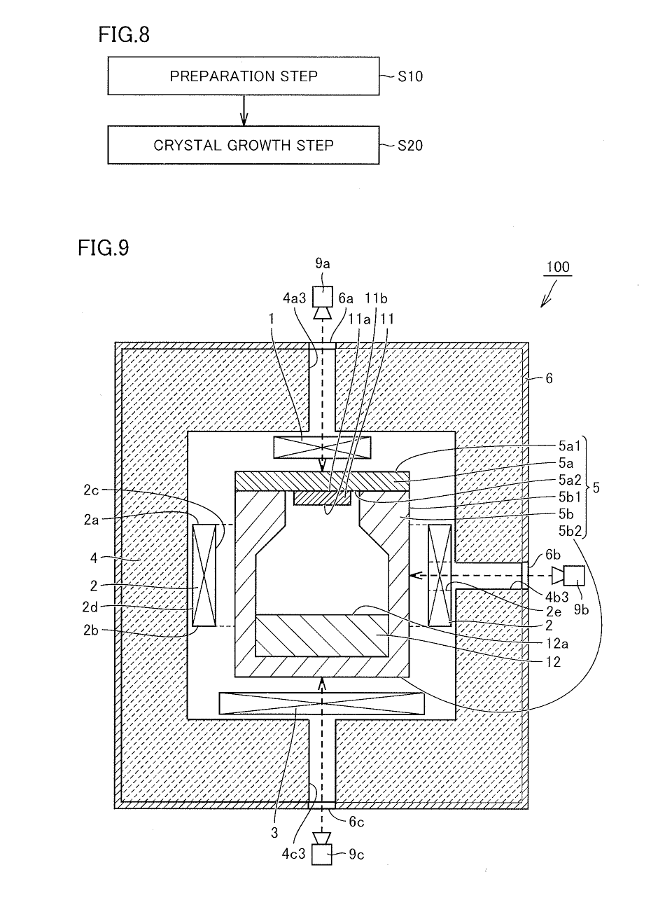

Next, a method of manufacturing a silicon carbide single crystal according to this embodiment is described. As shown in FIG. 8, the method of manufacturing a silicon carbide single crystal according to this embodiment includes a preparation step (S10) and a crystal growth step (S20).

First, the preparation step (S10: FIG. 8) is performed. In the preparation step (S10), manufacturing device 100 including heat insulator 4, upper resistive heater 1, lateral resistive heater 2, lower resistive heater 3, and crucible 5 is prepared (see FIG. 2). Further, seed crystal 11 and silicon carbide source material 12 are prepared. As shown in FIG. 9, silicon carbide source material 12 is disposed in accommodation unit 5b of crucible 5. Silicon carbide source material 12 is powders of polycrystalline silicon carbide, for example. Seed crystal 11 is fixed on seed crystal holding surface 5a2 of pedestal 5a with an adhesive, for example. Seed crystal 11 is a substrate of hexagonal silicon carbide having a polytype of 4H, for example. Seed crystal 11 has backside surface 11a fixed to seed crystal holding surface 5a2, and surface 11b opposite to backside surface 11a. Surface 11b has a diameter of 100 mm or more, for example, and preferably 150 mm or more. Surface 11b is a plane having an off angle of about 8° or less relative to a (0001) plane, for example. Seed crystal 11 is disposed such that surface 11b faces a surface 12a of silicon carbide source material 12.

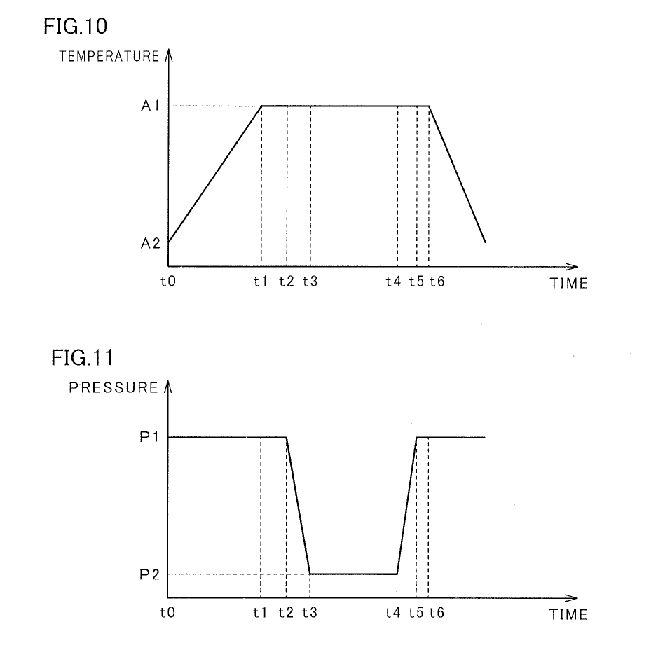

Then, the crystal growth step (S20: FIG. 8) is performed. In the crystal growth step (S20), crucible 5 is heated using upper resistive heater 1, lateral resistive heater 2 and lower resistive heater 3. As shown in FIG. 10, crucible 5 having a temperature A2 at time t0 is heated to a temperature A1 at time t1. Temperature A2 is room temperature, for example. Temperature A1 is 2000° C. or more and 2400° C. or less, for example. Both silicon carbide source material 12 and seed crystal 11 are heated such that the temperature decreases from bottom surface 5b2 toward top surface 5a1. Crucible 5 is maintained at temperature A1 between time t1 and time t6.

As shown in FIG. 11, the pressure in chamber 6 is maintained at a pressure P1 between time t0 and time t2. Pressure P1 is atmospheric pressure, for example. An atmospheric gas in chamber 6 is inert gas such as argon gas, helium gas or nitrogen gas.

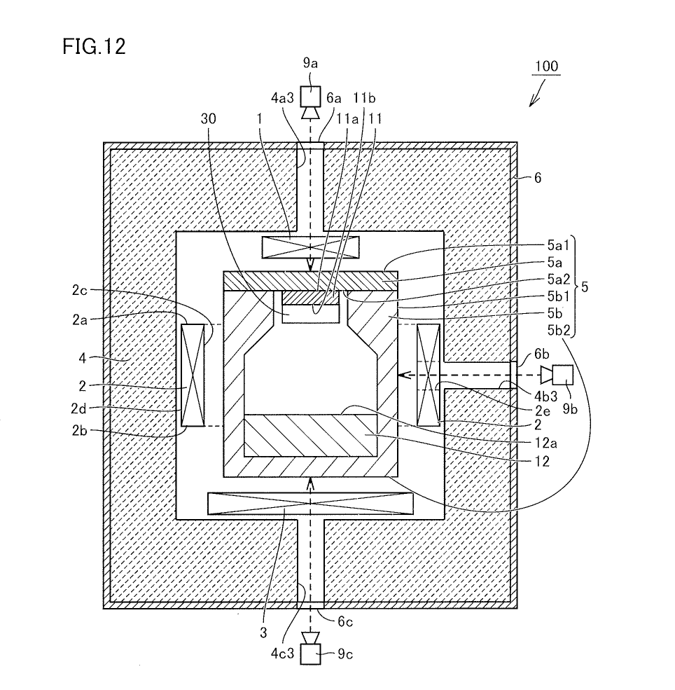

At time t2, the pressure in chamber 6 is reduced from pressure P1 to a pressure P2. Pressure P2 is 0.5 kPa or more and 2 kPa or less, for example. The pressure in chamber 6 is maintained at pressure P2 between time t3 and time t4. Silicon carbide source material 12 starts to sublimate between time t2 and time t3. The sublimated silicon carbide recrystallizes on surface 11b of seed crystal 11. Between time t3 and time t4, silicon carbide source material 12 continues to sublimate, whereby a silicon carbide single crystal 30 (FIG. 12) grows on surface 11b.

In the above-described crystal growing step, adjustment of the temperature of each of silicon carbide source material 12 and seed crystal 11 is implemented by controlling an amount of heat generated by each of upper resistive heater 1, lateral resistive heater 2 and lower resistive heater 3. Specifically, the temperature of bottom surface 5b2 of crucible 5 is measured using lower pyrometer 9c. The measured temperature of bottom surface 5b2 is transmitted to a control unit (not shown) of manufacturing device 100. The control unit controls the amount of heat generated by lower resistive heater 3 by means of power supplied to lower resistive heater 3 such that the temperature of bottom surface 5b2 agrees with a target temperature.

Likewise, the temperature of side surface 5b1 of crucible 5 is measured using lateral pyrometer 9b. The measured temperature of side surface 5b1 is transmitted to the control unit. The control unit controls the amount of heat generated by lateral resistive heater 2 by means of power supplied to lateral resistive heater 2 such that the temperature of side surface 5b1 agrees with a target temperature. Likewise, the temperature of top surface 5a1 of crucible 5 is measured using upper pyrometer 9a. The measured temperature of top surface 5a1 is transmitted to the control unit. The control unit controls the amount of heat generated by upper resistive heater 1 by means of power supplied to upper resistive heater 1 such that the temperature of top surface 5a1 agrees with a target temperature.

Then, as shown in FIG. 11, between time t4 and time t5, the pressure in chamber 6 increases from pressure P2 to pressure P1. Because of the pressure increase in chamber 6, the sublimation of silicon carbide source material 12 is suppressed. The crystal growing step is thus substantially completed. At time t6, the heating of crucible 5 is stopped to cool crucible 5. After the temperature of crucible 5 approaches the room temperature, silicon carbide single crystal 30 is removed from crucible 5.

<First Variation>

A first variation of the device of manufacturing a silicon carbide single crystal according to this embodiment is now described. The device of manufacturing a silicon carbide single crystal according to the first variation basically has the same configuration as that of manufacturing device 100 shown in FIGS. 1 and 2, except for the configuration of lateral resistive heater 2. Thus, the same or corresponding parts are designated by the same signs and the same description will not be repeated.

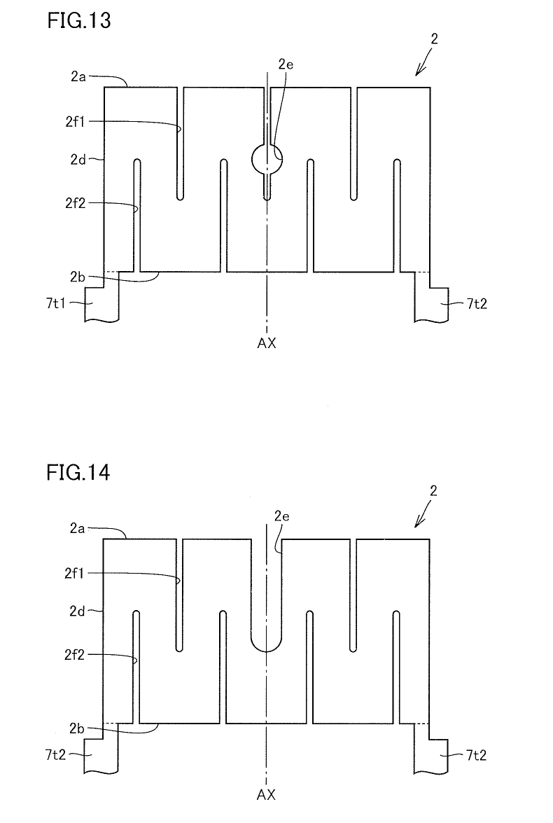

Although the above-described embodiment has illustrated the configuration in which opening 2e is provided continuously with first slit 2f1 on the side close to second surface 2b of lateral resistive heater 2, the position where opening 2e is disposed is set on the condition that opening 4b3, opening 6b and opening 2e are in communication with one another when lateral resistive heater 2 is disposed in heat insulator 4, as shown in FIGS. 1 and 2. Thus, as shown in FIG. 13, for example, opening 2e may be provided to overlap with first slit 2f1. Alternatively, although not shown, opening 2e may be provided in second portion 2x continuous with first slit 2f1, in a position separated from first slit 2f1.

Although the above-described embodiment has illustrated the configuration in which opening 2e has a round shape centered on axis AX (see FIG. 5), the shape of opening 2e is not necessarily limited to a round shape as long as it is line-symmetrical with axis AX as a symmetry axis. For example, as shown in FIG. 14, one of first slits 2f1 may be replaced by opening 2e. That is, opening 2e extends from first surface 2a toward second surface 2b. A minimum opening width of opening 2e is equal to or greater than the measurement diameter of the pyrometer forming lateral pyrometer 9b, and is, for example, about 3 to 5 mm.

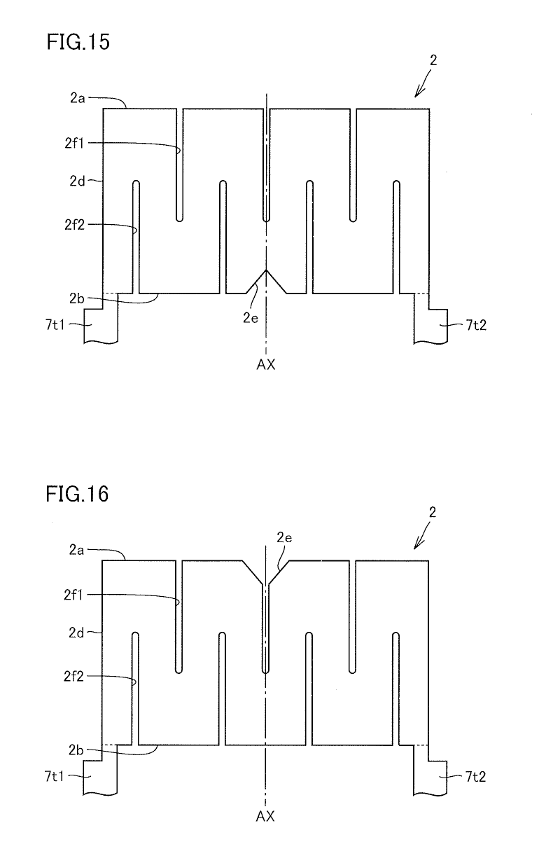

Alternatively, as shown in FIGS. 15 and 16, the shape of opening 2e may be such that its contour line is not closed. Opening 2e opens toward second surface 2b in FIG. 15, while opening 2e opens toward first surface 2a in FIG. 16. In both FIGS. 15 and 16, opening 2e has a line-symmetrical shape with axis AX passing through first slit 2f1 as a symmetry axis.

<Second Variation>

A second variation of the device of manufacturing a silicon carbide single crystal according to this embodiment is now described.

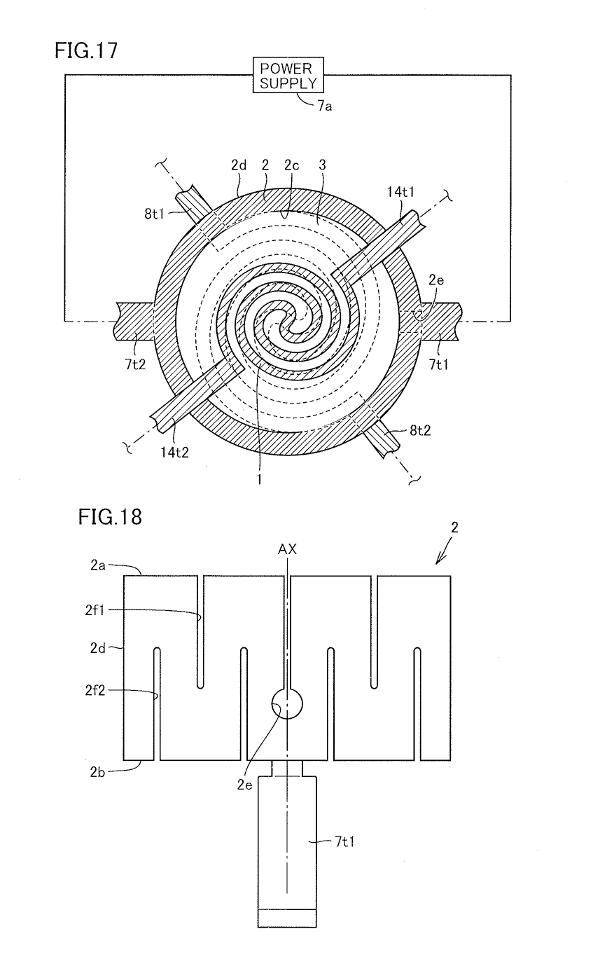

As shown in FIG. 17, when viewed along the direction from top surface 5a1 toward bottom surface 5b2, the pair of terminals 8t1 and 8t2 of lower resistive heater 3, the pair of terminals 7t1 and 7t2 of lateral resistive heater 2, and the pair of terminals 14t1 and 14t2 of upper resistive heater 1 are disposed in positions that do not overlap with one another. For example, directions in which first terminal 7t1, fifth terminal 14t1, third terminal 8t1, second terminal 7t2, sixth terminal 14t2 and fourth terminal 8t2 extend are displaced from each other by about 600.

In lateral resistive heater 2, opening 2e is disposed in a position overlapping with the other end of first terminal 7t1 when viewed from first surface 2a. When viewed from fourth surface 2d, as shown in FIG. 18, both opening 2e and first terminal 7t1 are disposed on axis AX passing through first slit 2f1.

Lateral resistive heater 2 is represented by an equivalent circuit formed of a pair of resistive elements connected in parallel between first terminal 7t1 and second terminal 7t2 and having the same resistance value. Accordingly, if opening 2e is disposed such that it is displaced from first terminal 7t1 and second terminal 7t2 when viewed from first surface 2a, a difference in resistance value occurs between one of the resistive elements and the other resistive element, which may result in failure to keep a balance in the amount of heat generation. In manufacturing device 100 according to this variation, therefore, opening 2e is disposed in a position where opening 2e at least partially overlaps with the other end of first terminal 7t1 or second terminal 7t2 when viewed from first surface 2a. This can prevent opening 2e from creating an imbalance in the amount of heat generation in lateral resistive heater 2.

<Third Variation>

A third variation of the device of manufacturing a silicon carbide single crystal according to this embodiment is now described. The device of manufacturing a silicon carbide single crystal according to the third variation basically has the same configuration as that of manufacturing device 100 shown in FIGS. 1 and 2. The device of manufacturing a silicon carbide single crystal according to the third variation, however, is different from the manufacturing device shown in FIGS. 1 and 2 mainly in that it includes an AC power supply 10 and a controller 20. Thus, the same or corresponding parts are designated by the same signs and the same description will not be repeated.

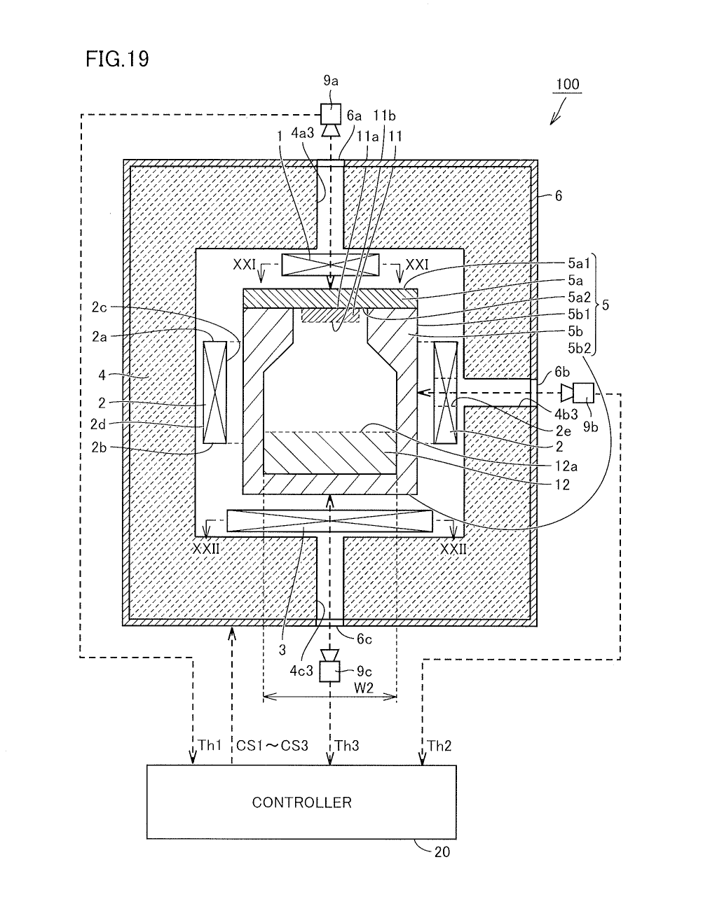

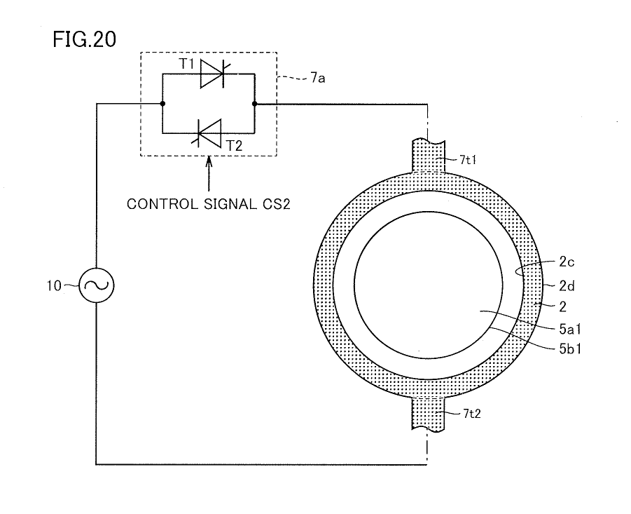

As shown in FIGS. 19 and 20, device 100 of manufacturing a silicon carbide single crystal may further include AC power supply 10 and controller 20. As shown in FIG. 20, first power supply 7a receives a supply of power from AC power supply 10, and supplies the power to lateral resistive heater 2. First power supply 7a is formed of, for example, an AC power regulator (APR). First power supply 7a includes, as an example, a thyristor switch formed of a pair of anti-parallel connected thyristors T1 and T2. By varying a control angle of thyristors T1 and T2 in accordance with a control signal CS2 from controller 20, the power supplied to lateral resistive heater 2 can be continuously adjusted from maximum power to minimum power.

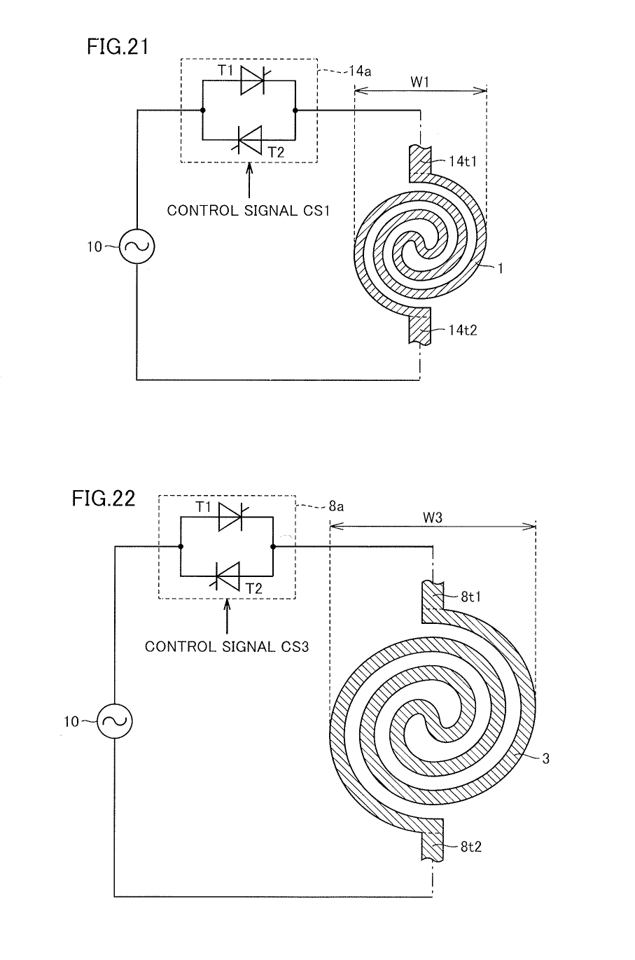

As shown in FIG. 21, second power supply 14a receives a supply of power from AC power supply 10, and supplies the power to upper resistive heater 1. Second power supply 14a is formed of a thyristor switch, for example, as with first power supply 7a. Second power supply 14a can continuously adjust the power supplied to upper resistive heater 1 from maximum power to minimum power in accordance with a control signal CS1 from controller 20.

As shown in FIG. 22, third power supply 8a receives a supply of power from AC power supply 10, and supplies the power to lower resistive heater 3. Third power supply 8a is formed of a thyristor switch, for example, as with first power supply 7a. Third power supply 8a can continuously adjust the power supplied to lower resistive heater 3 from maximum power to minimum power in accordance with a control signal CS3 from controller 20.

An AC power regulator employing a pulse width modulation (PWM) control scheme may be used for each of second power supply 14a, first power supply 7a and third power supply 8a. A variety of power supply circuits can be used, without being limited to the AC power regulator, for each of second power supply 14a, first power supply 7a and third power supply 8a, as long as it is configured to be able to receive a supply of power from AC power supply 10 and generate power supplied to the resistive heater.

As shown in FIG. 19, upper pyrometer 9a is provided outside chamber 6 in a position facing top surface 5a1 of crucible 5, and configured to be able to measure a temperature of top surface 5a1 through opening 4a3 and view port 6a. A temperature Th1 of top surface 5a1 measured by upper pyrometer 9a is transmitted to controller 20.

Lateral pyrometer 9b is provided outside chamber 6 in a position facing side surface 5b1 of crucible 5, and configured to be able to measure a temperature of side surface 5b1 through opening 4b3 and view port 6b. A temperature Th2 of side surface 5b1 measured by lateral pyrometer 9b is transmitted to controller 20.

Lower pyrometer 9c is provided outside chamber 6 in a position facing bottom surface 5b2 of crucible 5, and configured to be able to measure a temperature of bottom surface 5b2 through opening 4c3 and view port 6c. A temperature Th3 of bottom surface 5b2 measured by lower pyrometer 9c is transmitted to controller 20.

Typically, controller 20 mainly includes a CPU (Central Processing Unit), a memory region such as a RAM (Random Access Memory) or a ROM (Read Only Memory), and an input/output interface. Controller 20 performs temperature control of crucible 5 by causing the CPU to read a program prestored in the ROM or the like onto the RAM and execute the program. Controller 20 may at least partially be configured to execute prescribed numerical/logical operation processing by hardware such as an electronic circuit.

Temperature Th1 of top surface 5a1 from upper pyrometer 9a, temperature Th2 of side surface 5b1 from lateral pyrometer 9b, and temperature Th3 of bottom surface 5b2 from lower pyrometer 9c are illustrated in FIG. 19 as information input to controller 20. Although not shown, a detected value of the pressure in chamber 6 is also input to controller 20.

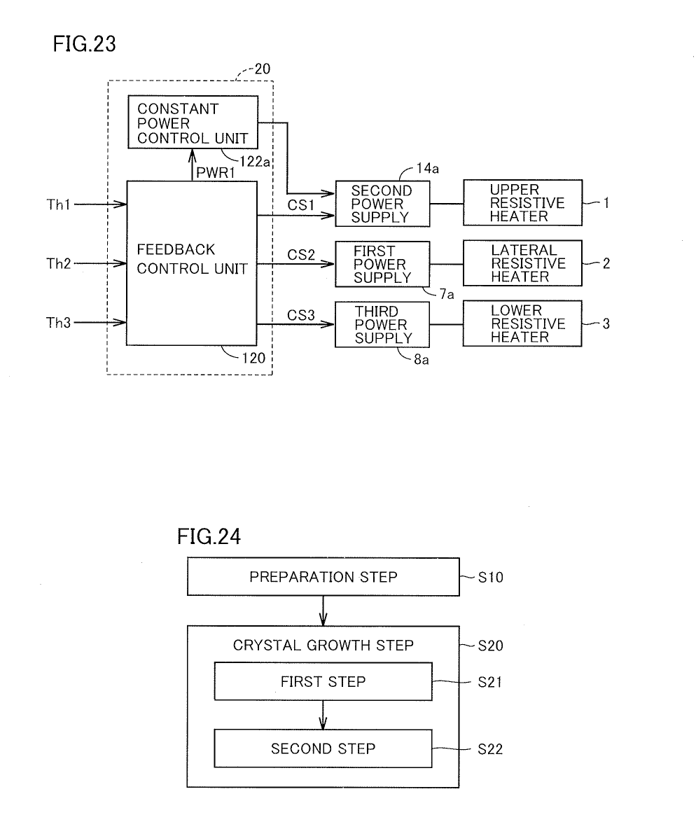

FIG. 23 is a functional block diagram illustrating the temperature control of crucible 5 in device 100 of manufacturing a silicon carbide single crystal according to this variation. It is noted that each functional block illustrated in the following block diagrams from FIG. 23 can be implemented by controller 20 executing software processing in accordance with a preset program. Alternatively, a circuit (hardware) having a function corresponding to this functional block can be configured in controller 20.

As shown in FIG. 23, controller 20 includes a feedback control unit 120 and a constant power control unit 122a. Feedback control unit 120 receives a measured value of temperature Th1 of top surface 5a1 from upper pyrometer 9a, receives a measured value of temperature Th2 of side surface 5b1 from lateral pyrometer 9b, and receives a measured value of temperature Th3 of bottom surface 5b2 from lower pyrometer 9c. Feedback control unit 120 feedback controls the power supplied to each of upper resistive heater 1, lateral resistive heater 2 and lower resistive heater 3 such that each of the measured values of temperatures Th1, Th2 and Th3 attains to its target value.

Controller 20 is also configured to perform, in addition to the feedback control, constant power control where the power supplied to the resistive heaters is fixed to constant power. In the step of growing a silicon carbide single crystal (S20: FIG. 24), controller 20 switches the control of the power supplied to the resistive heaters from the feedback control to the constant power control. The details of the switching from the feedback control to the constant power control will be described later.

(Method of Manufacturing Silicon Carbide Single Crystal)

Next, a method of manufacturing a silicon carbide single crystal according to this variation is described. As shown in FIG. 24, the method of manufacturing a silicon carbide single crystal according to this variation includes the preparation step (S10) and the crystal growth step (S20).

[Preparation Step (S10)]

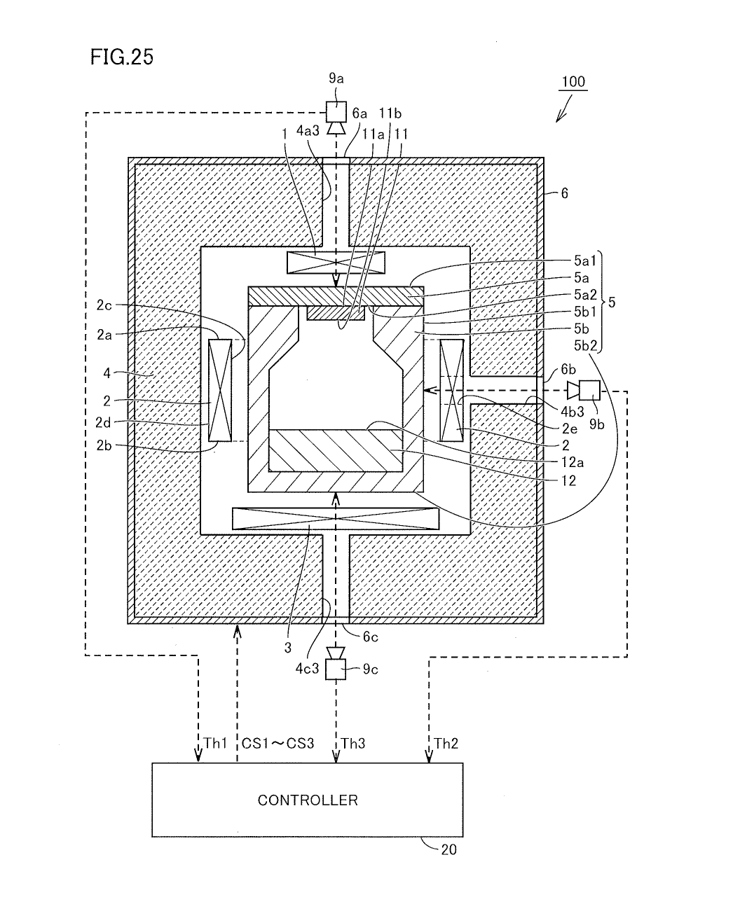

The preparation step (S10) is performed in a manner similar to the preparation step (S10) in FIG. 8. For example, device 100 of manufacturing a silicon carbide single crystal shown in FIG. 19 is prepared. Then, silicon carbide source material 12 and seed crystal 11 are disposed in crucible 5 (see FIG. 25).

[Crystal Growth Step (S20)]

In the crystal growth step (S20), power is supplied to upper resistive heater 1, lateral resistive heater 2 and lower resistive heater 3 to heat crucible 5, to sublimate silicon carbide source material 12 to thereby grow a silicon carbide single crystal on surface 11b of seed crystal 11.

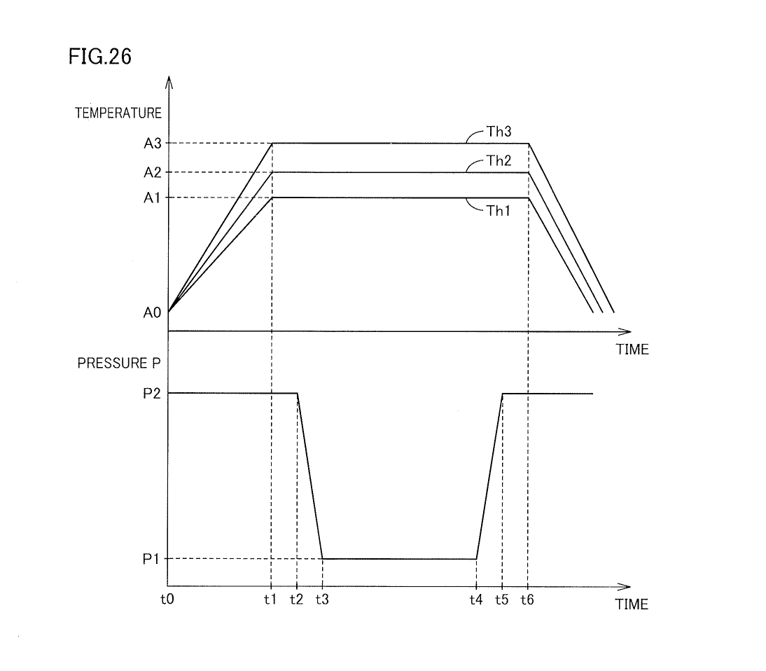

FIG. 26 is a diagram showing temporal variation in temperature of crucible 5 and pressure in chamber 6. As shown in FIG. 26, at time t0, each of temperature Th1 of top surface 5a1, temperature Th2 of side surface 5b1 and temperature Th3 of bottom surface 5b2 is a temperature A0. Temperature A0 is room temperature, for example. Between time t0 and time t1, temperature Th1 increases to temperature A1, temperature Th2 increases to temperature A2, and temperature Th3 increases to temperature A3. Although temperatures Th1, Th2 and Th3 reach temperatures A1, A2 and A3 simultaneously at time t1 in FIG. 26, they do not need to reach temperatures A1, A2 and A3 with the same timing.

Temperature A3 is equal to or higher than a temperature at which silicon carbide can sublimate, and is 2000° C. or more and 2400° C. or less, for example. Temperature A2 is lower than temperature A3, and temperature A1 is lower than temperature A2. Temperature A1 is a temperature at which the sublimated source material gas recrystallizes, and is 1900° C. or more and 2300° C. or less, for example. That is, both silicon carbide source material 12 and seed crystal 11 are heated such that the temperature decreases from bottom surface 5b2 toward top surface 5a1. Between time t1 and time t6, top surface 5a1 is maintained at temperature A1, side surface 5b1 is maintained at temperature A2, and bottom surface 5b2 is maintained at temperature A3.

The pressure in chamber 6 is maintained at pressure P2 between time t0 and time t2. Pressure P2 is atmospheric pressure, for example. An atmospheric gas in chamber 6 is inert gas such as argon gas, helium gas or nitrogen gas. At time t2, the pressure in chamber 6 is reduced from pressure P2 to pressure P1. Pressure P1 is 0.5 kPa or more and 2 kPa or less, for example. The timing of start of the pressure reduction in chamber 6 is not limited to a time after completion of the temperature increase in silicon carbide source material 12 and seed crystal 11, but may be a time during the temperature increase. That is, the pressure reduction in chamber 6 may be carried out in parallel with the temperature increase process. Silicon carbide source material 12 starts to sublimate between time t2 and time t3. The pressure in chamber 6 is maintained at pressure P1 between time t3 when the pressure reduction is completed and time t4.

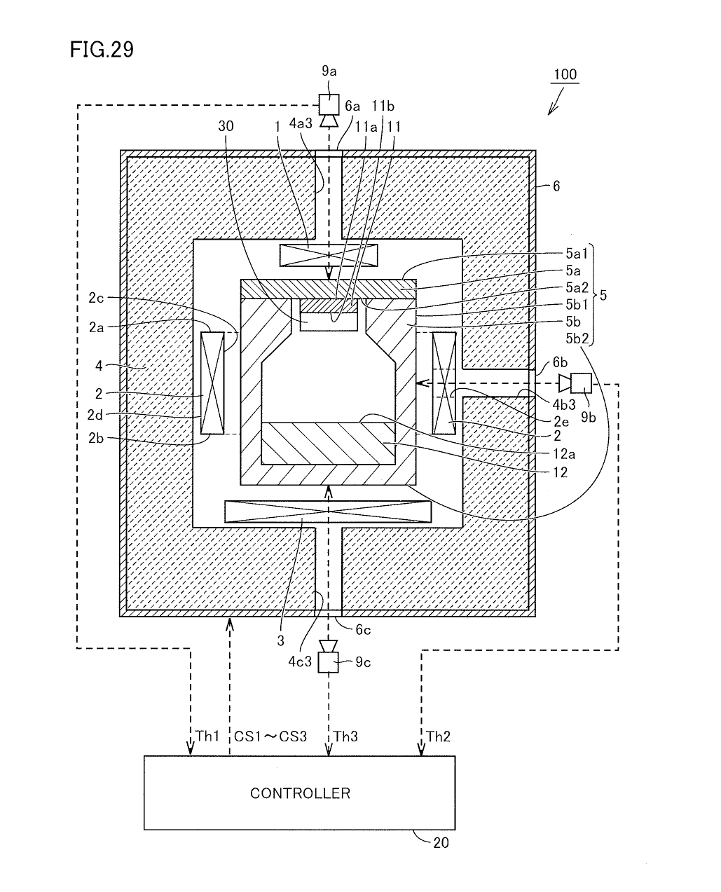

Between time t3 and time t4, silicon carbide source material 12 continues to sublimate as the pressure in chamber 6 is maintained at pressure P1. The sublimated silicon carbide recrystallizes on surface 11b of seed crystal 11. Thus, silicon carbide single crystal 30 (see FIG. 29) grows on surface 11b of seed crystal 11. During the silicon carbide single crystal growth, silicon carbide source material 12 is maintained at temperature A3 at which silicon carbide sublimates, and seed crystal 11 is maintained at temperature A1 at which silicon carbide recrystallizes.

[Control of Power to Resistive Heaters]

The temperature control of crucible 5 in the crystal growth step (S20) described above is implemented by controlling the power supplied to each of upper resistive heater 1, lateral resistive heater 2 and lower resistive heater 3. The control of the power supplied to the resistive heaters in the crystal growth step (S20) is now described.

As shown in FIG. 24, the crystal growth step (S20) includes a first step (S21) in which the power supplied to the heating unit is feedback controlled based on the temperatures of crucible 5 measured by the pyrometers, and a second step (S22) in which the power supplied to the heating unit is controlled to be constant power.

In this variation, as one embodiment of the first step (S21), the powers supplied to upper resistive heater 1, lateral resistive heater 2 and lower resistive heater 3, respectively, are feedback controlled based on the temperatures of crucible 5 measured by pyrometers 9a, 9b and 9c, respectively. In addition, as one embodiment of the second step (S22), the powers supplied to lateral resistive heater 2 and lower resistive heater 3, respectively, are feedback controlled based on the temperatures of crucible 5 measured by lateral pyrometer 9b and lower pyrometer 9c, respectively, and the power supplied to upper resistive heater 1 is controlled to be constant power.

[First Step (S21)]

In the first step (S21), supplied powers PWR1, PWR2 and PWR3 are feedback controlled such that the measured values of temperatures Th1, Th2 and Th3 agree with their target values, respectively. Such feedback control is implemented by feedback control unit 120 of controller 20 (see FIG. 23).

Specifically, feedback control unit 120 calculates power PWR1 supplied to upper resistive heater 1 by performing a control calculation of a difference between the measured value of temperature Th1 of top surface 5a1 and the target value for each control cycle. Then, feedback control unit 120 generates control signal CS1 for controlling second power supply 14a such that supplied power PWR1 thus calculated is provided to upper resistive heater 1. Feedback control unit 120 calculates power PWR2 supplied to lateral resistive heater 2 by performing a control calculation of a difference between the measured value of temperature Th2 of side surface 5b1 and the target value. Then, feedback control unit 120 generates control signal CS2 for controlling first power supply 7a such that supplied power PWR2 thus calculated is provided to lateral resistive heater 2. Feedback control unit 120 calculates power PWR3 supplied to lower resistive heater 3 by performing a control calculation of a difference between the measured value of temperature Th3 of bottom surface 5b2 and the target value. Then, feedback control unit 120 generates control signal CS3 for controlling third power supply 8a such that supplied power PWR3 thus calculated is provided to lower resistive heater 3.

Until each of temperatures Th1, Th2 and Th3 reaches a range where it can be measured by each of pyrometers 9a, 9b and 9c, however, the feedback control based on the measured temperature value cannot be performed, and therefore, each of supplied powers PWR1, PWR2 and PWR3 is controlled to be predetermined power.

[Second Step (S22)]

In the second step (S22), the control of the power supplied to upper resistive heater 1 is switched from the feedback control to the constant power control. The power supplied to upper resistive heater 1 in the second step (S22) is determined by calculation based on the power supplied to upper resistive heater 1 in the first step (S21). It is noted that the power supplied to lateral resistive heater 2 and the power supplied to lower resistive heater 3 continue to be feedback controlled during crystal growth. Therefore, attention will be focused on the control of the power supplied to upper resistive heater 1, which will be described low.

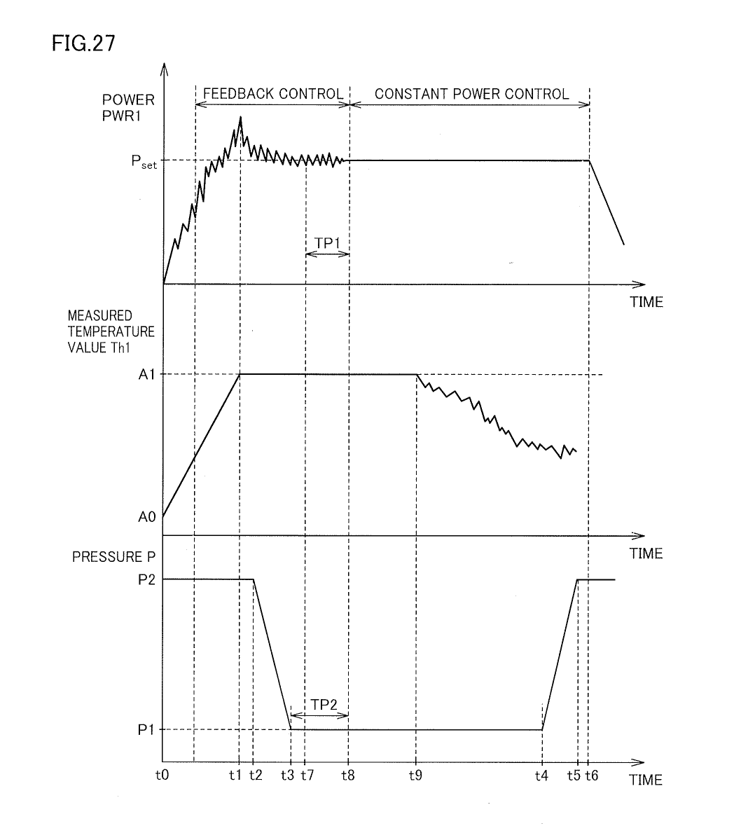

FIG. 27 is a diagram showing temporal variation in power PWR1 supplied to upper resistive heater 1, measured value Th1 of the temperature of top surface 5a1 from upper pyrometer 9a, and a pressure P in chamber 6.

As shown in FIG. 27, during a temperature increase process between time t0 and time t1, measured temperature value Th1 from upper pyrometer 9a increases from temperature A0 to temperature A1. In the temperature increase process, feedback control unit 120 of controller 20 performs the feedback control of power PWR1 supplied to upper resistive heater 1 such that measured temperature value Th1 agrees with a target value. Feedback control unit 120 starts performing the feedback control when measured temperature value Th1 reaches the range where it can be measured by upper pyrometer 9a.

After the temperature increase is completed at time t1, feedback control unit 120 performs the feedback control of supplied power PWR1 in order to maintain temperature Th1 of top surface 5a1 at temperature A1. That is, when a difference occurs between measured temperature value Th1 and temperature A1 after time t1, supplied power PWR1 is increased or decreased to eliminate the difference, so that measured temperature value Th1 is maintained at temperature A1. The feedback control of supplied power PWR1 is performed also during execution of the pressure reduction in crucible 5. After the pressure in chamber 6 reaches pressure P1 at time t3, a silicon carbide single crystal grows on surface 11b of seed crystal 11 between time t3 and time t4 during which the pressure is maintained at pressure P1.

Feedback control unit 120 performs the feedback control of supplied power PWR1 until time t8 when a prescribed time period TP2 elapses since time t3. During this time period TP2, constant power control unit 122a of controller 20 (see FIG. 23) obtains data indicative of supplied power PWR1 which has been set by feedback control unit 120. It is noted that the “data indicative of supplied power PWR1” may be a control command of supplied power PWR1 generated by feedback control unit 120, or may be an actual value of power supplied to upper resistive heater 1 from second power supply 14a.

Specifically, during time period TP1 from time t7 after time t3 to time t8, constant power control unit 122a obtains the data indicative of supplied power PWR1 and stores the data in the memory region for each prescribed cycle. It is preferred that time period TP1 start after the condition in crucible 5 has been stabilized after completion of the pressure reduction in chamber 6. For example, time t7 when time period TP1 starts is set to a timing at which about one hour elapses since time t3 when the pressure reduction was completed.

The length of time period TP1 is set, for example, to one hour or more and five hours or less. A cycle in which constant power control unit 122a obtains the data during time period TP1 is set, for example, to about 10 to 60 seconds. If the length of time period TP1 is set to one hour and the cycle in which the data is obtained is set to 10 seconds as an example, then 360 pieces of data are obtained during time period TP1.

After a lapse of time period TP1, constant power control unit 122a determines a set value Pset of supplied power PWR1 by calculation from the plurality of pieces of data obtained during time period TP1. Specifically, constant power control unit 122a determines set value Pset by calculation by performing statistical processing of the plurality of pieces of data. For example, constant power control unit 122a determines an average value of the plurality of pieces of data by calculation. Then, constant power control unit 122a determines the average value thus determined by calculation as set value Pset. It is noted that set value Pset does not need to agree with the average value, but may be within a certain range above or below the average value. For example, constant power control unit 122a determines set value Pset within a range of ±5% of the average value.

As the statistical processing of the plurality of pieces of data, processing of determining a median value of the plurality of pieces of data by calculation, processing of determining a mode value of the plurality of pieces of data by calculation or the like may be executed, in addition to the processing of determining an average value of the plurality of pieces of data by calculation. In the processing of determining an average value by calculation, the plurality of pieces of data from which abnormal values have been excluded may be averaged. For example, the pieces of data in the top 10% or higher and the pieces of data in the bottom 10% or lower of a distribution of the plurality of pieces of data may be excluded as abnormal values.

Constant power control unit 122a generates control signal CS1 for controlling second power supply 14a such that power is supplied to upper resistive heater 1 in accordance with set value Pset thus determined by calculation. Consequently, the control of the power supplied to upper resistive heater 1 is switched from the feedback control to the constant power control. The constant power control is performed during a period from time t8 to time t6 when the heating of crucible 5 is stopped. That is, the constant power control is performed during a period from time t8 to at least time t4 when the silicon carbide single crystal growth is completed.

As shown in FIG. 27, after the switching to the constant power control, constant power Pset independent of measured temperature value Th1 from upper pyrometer 9a is supplied to upper resistive heater 1. This constant power is set based on supplied power PWR1 feedback controlled in order to maintain the temperature of top surface 5a1 at temperature A1. In other words, the constant power is capable of maintaining top surface 5a1 at temperature A1 at which seed crystal 11 recrystallizes. Accordingly, measured temperature value Th1 is maintained at temperature A1 after time t8 as well.

Here, it is assumed that it has become difficult to measure the temperature of top surface 5a1 due to the occurrence of blockage of opening 4a3 at time t9 during execution of the constant power control. Measured temperature value Th1 from upper pyrometer 9a varies as shown in FIG. 27, resulting in difficulty for controller 20 to know the actual temperature of top surface 5a1. According to this variation, even in such a case, the constant power in accordance with set value Pset continues to be supplied to upper resistive heater 1, thus allowing upper resistive heater 1 to continue to generate a constant amount of heat. Consequently, the temperature of top surface 5a1 is maintained at temperature A1 after time t9 as well. As a result, temperature variation in top surface 5a1 can be suppressed even after the occurrence of blockage of opening 4a3 due to the recrystallized silicon carbide.

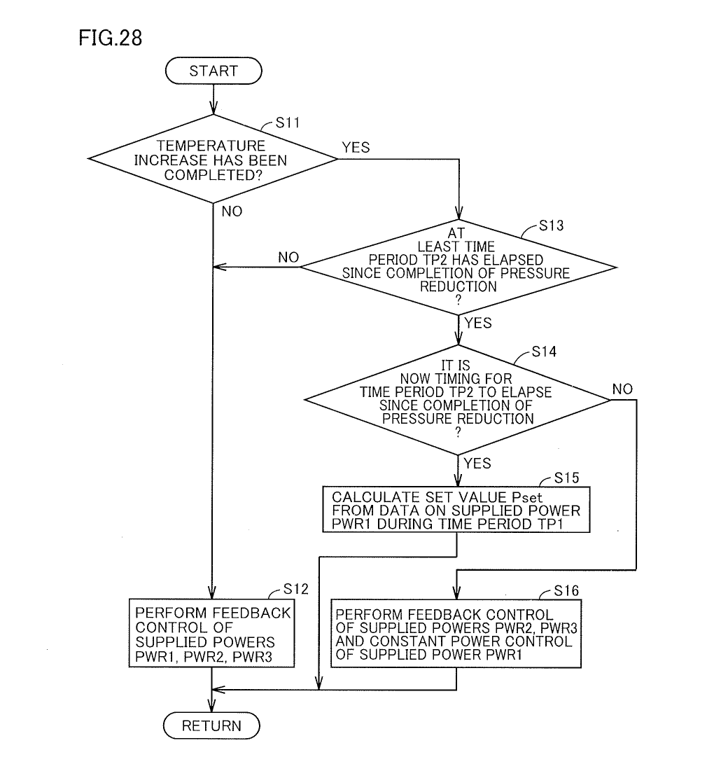

FIG. 28 is a flowchart showing a control process procedure executed by controller 20 in order to implement the switching of the control of upper resistive heater 1. The control process shown in FIG. 28 is repeatedly executed for each control cycle.

As shown in FIG. 28, first, in step S11, it is determined whether the temperature increase in silicon carbide source material 12 and seed crystal 11 has been completed or not. If it is determined that the temperature increase has not been completed (NO determination in S11), in step S12, the feedback control of supplied powers PWR1, PWR2 and PWR3 based on the measured values of temperatures Th1, Th2 and Th3 is performed.

If it is determined that the temperature increase has been completed (YES determination in S11), on the other hand, in step S13, it is determined whether at least time period TP2 has elapsed or not since the time when the pressure reduction in chamber 6 was completed. Time period TP2 is set, as shown in FIG. 27, to a time from time t3 when the pressure reduction is completed to time t8 when time period TP1 during which the data indicative of supplied power PWR1 is obtained ends.

If at least time period TP2 has not elapsed since the time when the pressure reduction was completed (NO determination in S13), in step S12, the feedback control of supplied powers PWR1, PWR2 and PWR3 is performed. If at least time period TP2 has elapsed since the time when the pressure reduction was completed (YES determination in S13), the process proceeds to step S14 where it is determined whether it is now timing for time period TP2 to elapse or not since the time when the pressure reduction was completed. If it is determined that it is now timing for time period TP2 to elapse since the time when the pressure reduction was completed (YES determination in S14), in step S15, set value Pset of supplied power PWR1 is determined by calculation from the plurality of pieces of data obtained during time period TP1.

If it is determined that the timing for time period TP2 to elapse since the time when the pressure reduction was completed has elapsed (NO determination in S14), on the other hand, in step S16, the constant power control is performed on power PWR1 supplied to upper resistive heater 1. It is noted that power PWR2 supplied to lateral resistive heater 2 and power PWR3 supplied to lower resistive heater 3 continue to be feedback controlled.

Returning to FIG. 26, between time t4 and time t5, the pressure in chamber 6 increases from pressure P1 to pressure P2. Because of the pressure increase in chamber 6, the sublimation of silicon carbide source material 12 is suppressed. The silicon carbide single crystal growth is thus substantially completed. At time t6, the heating of crucible 5 is stopped to cool crucible 5. After the temperature of crucible 5 approaches the room temperature, silicon carbide single crystal 30 is removed from crucible 5 (see FIG. 29).

<Fourth Variation>

Although the third variation above has described the configuration where the control of the power supplied to upper resistive heater 1 is switched from the feedback control to the constant power control in the second step (S22), the control of the power supplied to lateral resistive heater 2 may be switched. The power supplied to lateral resistive heater 2 in the second step (S22) is determined by calculation based on the power supplied to lateral resistive heater 2 in the first step (S21). According to this configuration, even when it has become difficult to measure the temperature of side surface 5b1 due to the occurrence of blockage of opening 4b3, the temperature of side surface 5b1 can be maintained at temperature A2.

Specifically, in the crystal growth step (S20), the power supplied to each of upper resistive heater 1, lateral resistive heater 2 and lower resistive heater 3 is feedback controlled by feedback control unit 120 during time period TP1. During time period TP1, constant power control unit 122a obtains data indicative of supplied power PWR2 and stores the data in the memory region for each prescribed cycle. Then, after a lapse of time period TP1, constant power control unit 122a determines set value Pset of supplied power PWR2 by calculation by performing statistical processing of the data obtained during time period TP1.

Then, during a period from time t8 after the lapse of time period TP1 to at least time t4 when the silicon carbide single crystal growth is completed, the power supplied to each of upper resistive heater 1 and lower resistive heater 3 is feedback controlled. Meanwhile, constant power Pset independent of measured temperature value Th2 from lateral pyrometer 9b is supplied to lateral resistive heater 2.

<Fifth Variation>

Although the switching from the feedback control to the constant power control is done once in the crystal growth step (S20) in the above-described third variation, the switching may be done a plurality of times. That is, the first step (S21) in which the feedback control is performed and the second step (S22) in which the constant power control is performed may be alternately repeated during crystal growth.

For example, controller 20 monitors measured temperature value Th1 from upper pyrometer 9a during execution of the second step (S22), and determines whether measured temperature value Th1 is within a range of ±10% of temperature A1 or not. If it is determined that measured temperature value Th1 is within that range, controller 20 proceeds to the first step (S21) to switch the control of the power to upper resistive heater 1 from the constant power control to the feedback control. Then, after the feedback control is performed again for a prescribed time period, set value Pset is determined by calculation based on the data indicative of supplied power PWR1 obtained during this prescribed time period. Consequently, in the second step (S22) subsequent to this first step (S21), power is supplied to upper resistive heater 1 in accordance with set value Pset which has been determined by calculation in the immediately preceding first step (S21).

By alternately repeating the feedback control and the constant power control in this manner, the power supplied to upper resistive heater 1 during execution of the constant power control is updated to set value Pset based on supplied power PWR1 in the immediately preceding feedback control. Consequently, during crystal growth, upper resistive heater 1 can continue to generate an amount of heat for maintaining the temperature of top surface 5a1 at temperature A1.

<Sixth Variation>

(Device of Manufacturing Silicon Carbide Single Crystal)

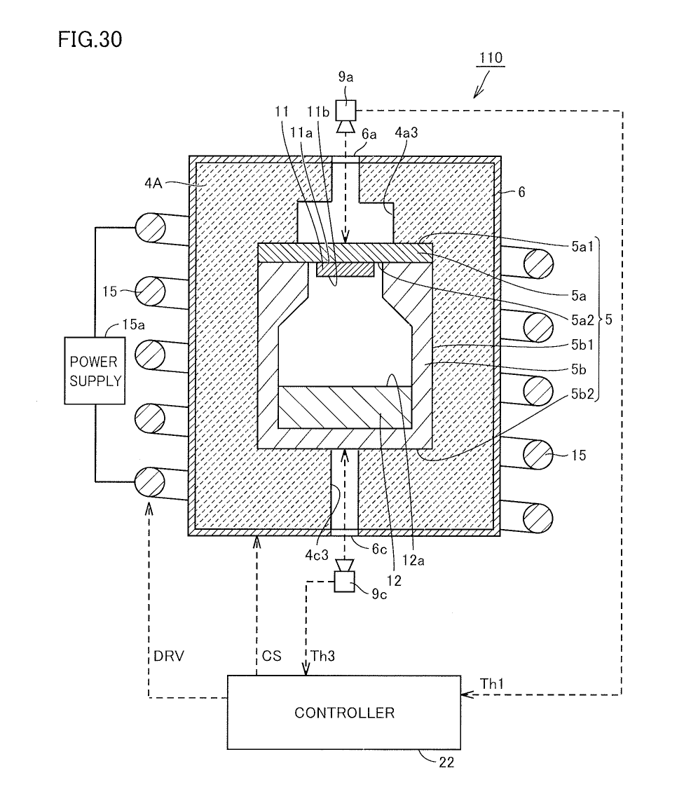

As shown in FIG. 30, a device 110 of manufacturing a silicon carbide single crystal according to a sixth variation basically has the same configuration as that of manufacturing device 100 according to the third variation shown in FIG. 19. Manufacturing device 110, however, is different from manufacturing device 100 in that it includes a high-frequency heating coil 15 instead of upper resistive heater 1, lateral resistive heater 2 and lower resistive heater 3, as the heating unit for heating crucible 5, that it includes a heat insulator 4A instead of heat insulator 4, and that it includes a controller 22 instead of controller 20. Thus, the same or corresponding parts are designated by the same signs and the same description will not be repeated.

[High-Frequency Heating Coil]

As shown in FIG. 30, high-frequency heating coil 15 is wound around the circumference of crucible 5. High-frequency heating coil 15 is preferably disposed outside heat insulator 4A when used as the heating unit. It is noted that high-frequency heating coil 15 may be disposed outside chamber 6, or may be disposed between heat insulator 4A and chamber 6.

High-frequency heating coil 15 is configured to be able to adjust each of the temperature of top surface 5a1 and the temperature of bottom surface 5b2. For this purpose, high-frequency heating coil 15 is configured such that it can be displaced in a vertical direction of crucible 5 (which corresponds to an up-down direction in FIG. 30) in accordance with a drive signal DRV from controller 22.

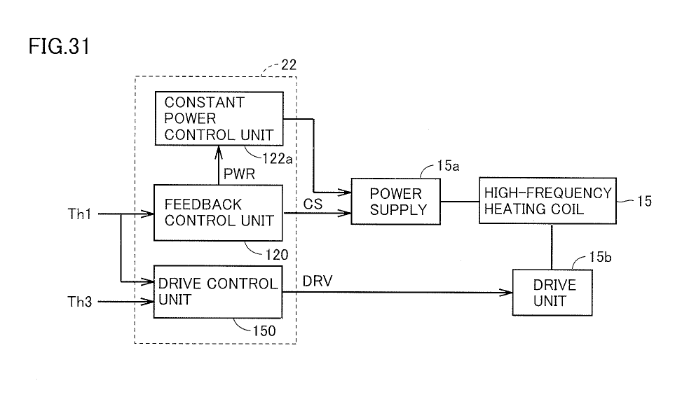

A power supply 15a (see FIG. 31) receives a supply of power from an AC power supply (not shown), and supplies the power to high-frequency heating coil 15. Power supply 15a includes a thyristor switch, for example. Power supply 15a can continuously adjust the power supplied to high-frequency heating coil 15 from maximum power to minimum power in accordance with a control signal CS from controller 22.

[Heat Insulator]

As shown in FIG. 30, heat insulator 4A is configured to be able to accommodate crucible 5. Heat insulator 4A is made of the same material as that of heat insulator 4. Heat insulator 4A is provided to surround the circumference of crucible 5 when crucible 5 is disposed in chamber 6.

Heat insulator 4A is provided with opening 4a3 such that top surface 5a1 is partially exposed at heat insulator 4A. Chamber 6 is provided with view port 6a in communication with opening 4a3. An opening diameter of opening 4a3 on the side facing top surface 5a1 is greater than an opening diameter of opening 4a3 on the side facing chamber 6. Thus, a gap is formed between an inner surface of heat insulator 4A and top surface 5a1. With heat released toward this gap from top surface 5a1, the temperature of top surface 5a1 is maintained at a temperature slightly lower than the temperature of bottom surface 5b2. This temperature difference contributes to forming a temperature gradient required for the sublimation and recrystallization between seed crystal 11 disposed on the side close to top surface 5a1 and silicon carbide source material 12 disposed on the side close to bottom surface 5b2. Heat insulator 4A is provided with opening 4c3 such that bottom surface 5b2 is partially exposed at heat insulator 4A. Chamber 6 is provided with view port 6c in communication with opening 4c3.

As shown in FIG. 30, upper pyrometer 9a is provided outside chamber 6 in a position facing top surface 5a1, and configured to be able to measure the temperature of top surface 5a1 through opening 4a3 and view port 6a. Lower pyrometer 9c is provided outside chamber 6 in a position facing bottom surface 5b2, and configured to be able to measure the temperature of bottom surface 5b2 through opening 4c3 and view port 6c.

[Controller]

Controller 22 performs temperature control of crucible 5 by causing a CPU to read a program prestored in a ROM or the like onto a RAM and execute the program, in a manner similar to controller 20. Temperature Th1 of top surface 5a1 from upper pyrometer 9a, and temperature Th3 of bottom surface 5b2 from lower pyrometer 9c are illustrated in FIG. 30 as information input to controller 22. Although not shown, a detected value of the pressure in chamber 6 is also input to controller 22.

FIG. 31 is a functional block diagram illustrating the temperature control of crucible 5 in device 110 of manufacturing a silicon carbide single crystal according to the sixth variation. As shown in FIG. 31, controller 22 includes feedback control unit 120, constant power control unit 122a, and a drive control unit 150. Feedback control unit 120 receives a measured value of temperature Th1 of top surface 5a1 from upper pyrometer 9a. Feedback control unit 120 feedback controls the power supplied to high-frequency heating coil 15 such that the measured value of temperature Th1 attains to its target value.

Constant power control unit 122a is configured to be able to perform constant power control where the power supplied to high-frequency heating coil 15 is fixed to constant power. In the step of growing a silicon carbide single crystal (S20: FIG. 24), controller 22 switches the control of the power supplied to high-frequency heating coil 15 from the feedback control to the constant power control.

Drive control unit 150 receives a measured value of temperature Th1 of top surface 5a1 from upper pyrometer 9a, and receives a measured value of temperature Th3 of bottom surface 5b2 from lower pyrometer 9c. Drive control unit 150 is configured to be able to adjust the position of high-frequency heating coil 15 so as to cause a desired temperature difference between temperature Th1 and temperature Th3.

(Method of Manufacturing Silicon Carbide Single Crystal)

Next, a method of manufacturing a silicon carbide single crystal according to the sixth variation is described. The method of manufacturing a silicon carbide single crystal according to the sixth variation is basically the same as the method of manufacturing a silicon carbide single crystal according to the third variation. That is, the method of manufacturing a silicon carbide single crystal according to the sixth variation includes the preparation step (S10: FIG. 7) and the crystal growth step (S20: FIG. 7). In the crystal growth step (S20), power is supplied to high-frequency heating coil 15 to heat crucible 5, to sublimate silicon carbide source material 12 to thereby grow a silicon carbide single crystal on surface 11b of seed crystal 11.

The method of manufacturing a silicon carbide single crystal according to the sixth variation is different from the method of manufacturing a silicon carbide single crystal according to the third variation in terms of the temperature control of crucible 5 in the crystal growth step (S20). The temperature control of crucible 5 in the crystal growth step (S20) is implemented by controlling an amount of heat generated by high-frequency heating coil 15 by means of the power supplied to high-frequency heating coil 15, and by controlling the position of high-frequency heating coil 15 in the vertical direction, as will be described below.

[Control of Power Supplied to High-Frequency Heating Coil]

The crystal growth step (S20) includes the first step (S21) and the second step (S22). In the sixth variation, as one embodiment of the first step (S21), the power supplied to high-frequency heating coil 15 is feedback controlled based on the temperature of crucible 5 measured by upper pyrometer 9a. In addition, as one embodiment of the second step (S22), the power supplied to high-frequency heating coil 15 is controlled to be constant power.

[First Step (S21)]

In the first step (S21), feedback control where power PWR supplied to high-frequency heating coil 15 is increased or decreased is performed such that the measured value of temperature Th1 agrees with a target value. Such feedback control is implemented by feedback control unit 120 of controller 22 (FIG. 31).

Specifically, feedback control unit 120 calculates power PWR supplied to high-frequency heating coil 15 by performing a control calculation of a difference between the measured value of temperature Th1 of top surface 5a1 and the target value for each control cycle. Then, feedback control unit 120 generates control signal CS for controlling power supply 15a such that supplied power PWR thus calculated is provided to high-frequency heating coil 15. Until temperature Th1 reaches a range where it can be measured by pyrometer 9a, however, the feedback control based on the measured temperature value cannot be performed, and therefore, supplied power PWR is controlled to be predetermined power.

[Second Step (S22)]

In the second step (S22), the control of the power supplied to high-frequency heating coil 15 is switched from the feedback control to the constant power control. The power supplied to high-frequency heating coil 15 in the second step (S22) is determined by calculation based on the power supplied to high-frequency heating coil 15 in the first step (S21). The switching of the control of high-frequency heating coil 15 is basically the same as the switching of the control of the resistive heaters according to the third embodiment. That is, the switching of the control of high-frequency heating coil 15 can be explained by replacing power PWR1 supplied to upper resistive heater 1 shown in FIG. 27 by power PWR supplied to high-frequency heating coil 15.

In the sixth variation, too, in a manner similar to the third variation, feedback control unit 120 performs the feedback control of supplied power PWR during execution of the temperature increase in crucible 5 and the pressure reduction in crucible 5 (between time t0 and time t3). Then, when the pressure reduction in chamber 6 is completed and crystal growth starts at time t3, feedback control unit 120 performs the feedback control of supplied power PWR until time t8 when prescribed time period TP2 elapses since time t3.

During this time period TP2, in time period TP1 from time t7 after time t3 to time t8, constant power control unit 122a obtains data indicative of supplied power PWR which has been set by feedback control unit 120 for each prescribed cycle. Then, after a lapse of time period TP1, constant power control unit 122a determines set value Pset of supplied power PWR by calculation by performing statistical processing of the plurality of pieces of data obtained during time period TP1.

Constant power control unit 122a generates control signal CS for controlling power supply 15a such that power is supplied to high-frequency heating coil 15 in accordance with set value Pset thus determined by calculation. Consequently, the control of the power supplied to high-frequency heating coil 15 is switched from the feedback control to the constant power control. The constant power control is performed during a period from time t8 to at least time t4 when the silicon carbide single crystal growth is completed.

After the switching to the constant power control, constant power Pset independent of measured temperature value Th1 from upper pyrometer 9a is supplied to high-frequency heating coil 15. Accordingly, even when it has become difficult to measure the temperature of top surface 5a1 due to the occurrence of blockage of opening 4b3 during execution of the constant power control, the constant power in accordance with set value Pset continues to be supplied to high-frequency heating coil 15, thus allowing the temperature of top surface 5a1 to be maintained at temperature A1.

[Position Adjustment of High-Frequency Heating Coil]

In the crystal growth step (S20), the position of high-frequency heating coil 15 is adjusted by drive control unit 150 (FIG. 31) in parallel with the above-described control of the supplied power.

Specifically, drive control unit 150 calculates a difference between temperature Th3 of bottom surface 5b2 measured by lower pyrometer 9c and temperature Th1 of top surface 5a1 measured by upper pyrometer 9a. Then, drive control unit 150 generates drive signal DRV for controlling the position of high-frequency heating coil 15 in the vertical direction such that the difference agrees with a desired temperature difference (temperature A3-temperature A1). Generated drive signal DRV is transmitted to a drive unit 15b (see FIG. 31). Drive unit 15b is configured to be able to move high-frequency heating coil 15 in the vertical direction. With drive unit 15b moving high-frequency heating coil 15 in accordance with drive signal DRV, the temperature difference between top surface 5a1 and bottom surface 5b2 is adjusted. In this manner, a temperature gradient required for the sublimation and recrystallization is formed between silicon carbide source material 12 and seed crystal 1.

Regarding the position of high-frequency heating coil 15 during execution of the constant power control, high-frequency heating coil 15 may be fixed to a certain position based on the position of high-frequency heating coil 15 during time period TP1. For example, drive control unit 150 obtains data indicative of the position of high-frequency heating coil 15 for each prescribed cycle during time period TP1. Then, after a lapse of time period TP1, drive control unit 150 determines the position of high-frequency heating coil 15 by calculation by performing statistical processing of the plurality of pieces of data obtained during time period TP1.

<Seventh Variation>

Although the temperature control of crucible 5 is implemented by the control of the power supplied to high-frequency heating coil 15 and the position adjustment of high-frequency heating coil 15 in the above-described sixth variation, the temperature control can be also implemented by forming high-frequency heating coil 15 of a plurality of coils that can be controlled independently of one another.

(Device of Manufacturing Silicon Carbide Single Crystal)

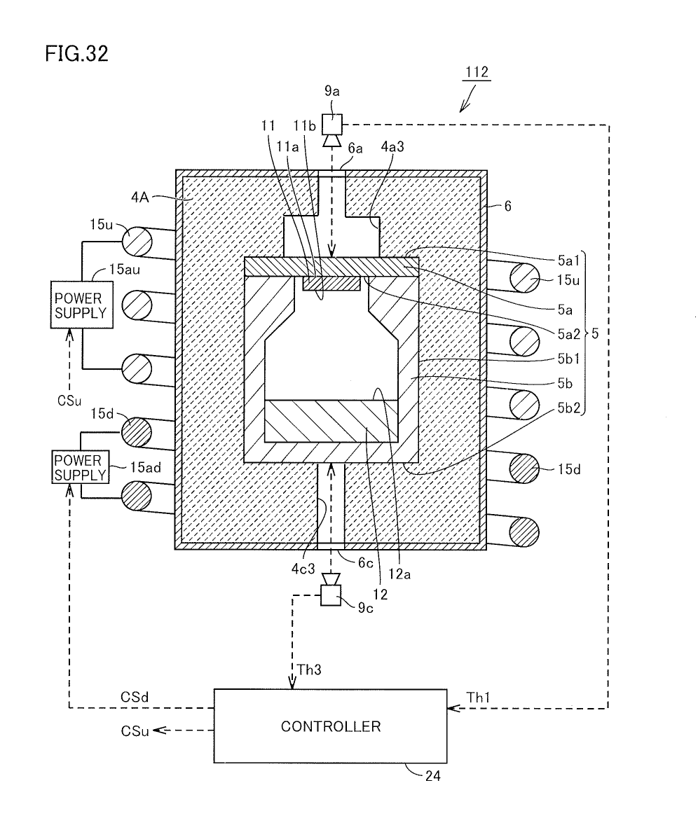

As shown in FIG. 32, a device 112 of manufacturing a silicon carbide single crystal according to a seventh variation basically has the same configuration as that of manufacturing device 110 according to the sixth variation shown in FIG. 3, however, is different from manufacturing device 110 in that the high-frequency heating coil is formed of a first coil 15u and a second coil 15d, and that it includes a controller 24 instead of controller 22. Thus, the same or corresponding parts are designated by the same signs and the same description will not be repeated.

[High-Frequency Heating Coil]

First coil 15u is wound around the circumference of crucible 5 on the side close to top surface 5a1. A power supply 15au receives a supply of power from an AC power supply (not shown), and supplies the power to first coil 15u. Power supply 15au includes a thyristor switch, for example. Power supply 15au can continuously adjust the power supplied to first coil 15u from maximum power to minimum power in accordance with a control signal CSu from controller 24.

Second coil 15d is wound around the circumference of crucible 5 on the side close to bottom surface 5b2. A power supply 15ad receives a supply of power from the AC power supply (not shown), and supplies the power to second coil 15d. Power supply 15ad includes a thyristor switch, for example. Power supply 15ad can continuously adjust the power supplied to second coil 15d from maximum power to minimum power in accordance with a control signal CSd from controller 24.

[Controller]

Controller 24 performs temperature control of crucible 5 by causing a CPU to read a program prestored in a ROM or the like onto a RAM and execute the program, in a manner similar to controller 22. Temperature Th1 of top surface 5a1 from upper pyrometer 9a, and temperature Th3 of bottom surface 5b2 from lower pyrometer 9c are illustrated in FIG. 32 as information input to controller 24. Although not shown, a detected value of the pressure in chamber 6 is also input to controller 24.

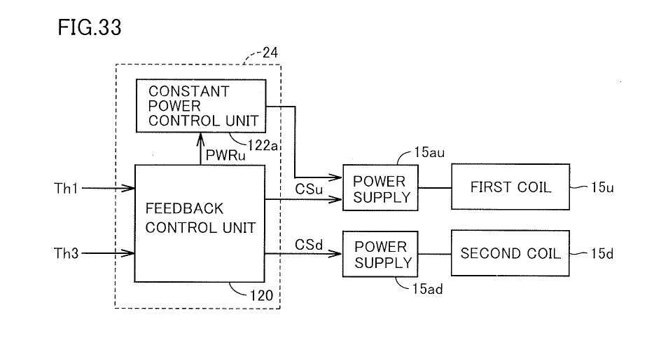

FIG. 33 is a functional block diagram illustrating the temperature control of crucible 5 in device 112 of manufacturing a silicon carbide single crystal according to this variation. As shown in FIG. 33, controller 24 includes feedback control unit 120 and constant power control unit 122a.

Feedback control unit 120 receives a measured value of temperature Th1 of top surface 5a1 from upper pyrometer 9a, and receives a measured value of temperature Th3 of bottom surface 5b2 from lower pyrometer 9c. Feedback control unit 120 feedback controls the power supplied to each of first coil 15u and second coil 15d such that each of the measured values of temperatures Th1 and Th3 attains to its target value.

Constant power control unit 122a is configured to be able to perform constant power control where the power supplied to first coil 15u is fixed to constant power. In the step of growing a silicon carbide single crystal (S20: FIG. 24), controller 24 switches the control of the power supplied to first coil 15u from the feedback control to the constant power control.

<Method of Manufacturing Silicon Carbide Single Crystal>

Next, a method of manufacturing a silicon carbide single crystal according to this variation is described. The method of manufacturing a silicon carbide single crystal according to this variation is basically the same as the method of manufacturing a silicon carbide single crystal according to the sixth variation. That is, the method of manufacturing a silicon carbide single crystal according to this variation includes the preparation step (S10: FIG. 7) and the crystal growth step (S20: FIG. 7). The method of manufacturing a silicon carbide single crystal according to this variation is different from the method of manufacturing a silicon carbide single crystal according to the sixth variation in terms of the temperature control of crucible 5 in the crystal growth step (S20). In the crystal growth step (S20) according to this variation, power is supplied to first coil 15u and second coil 15d to heat crucible 5, to sublimate silicon carbide source material 12 to thereby grow a silicon carbide single crystal on surface 11b of seed crystal 11.

[Control of Power Supplied to First Coil]

The crystal growth step (S20) includes the first step (S21) and the second step (S22). In this variation, as one embodiment of the first step (S21), the powers supplied to first coil 15u and second coil 15d, respectively, are feedback controlled based on the temperatures of crucible 5 measured by upper pyrometer 9a and lower pyrometer 9c, respectively. In addition, as one embodiment of the second step (S22), the power supplied to second coil 15d is feedback controlled based on the temperature of crucible 5 measured by lower pyrometer 9c, and the power supplied to first coil 15u is controlled to be constant power.

[First Step (S21)]

In the first step (S21), feedback control where the powers supplied to first coil 15u and second coil 15d are increased or decreased is performed such that the measured values of temperatures Th1 and Th3 agree with their target values, respectively. Such feedback control is implemented by feedback control unit 120 of controller 24 (see FIG. 33).

Specifically, feedback control unit 120 calculates power PWRu supplied to first coil 15u by performing a control calculation of a difference between the measured value of temperature Th1 of top surface 5a1 and the target value for each control cycle. Then, feedback control unit 120 generates control signal CSu for controlling power supply 15au such that supplied power PWRu thus calculated is provided to first coil 15u. Feedback control unit 120 also calculates power PWRd supplied to second coil 15d by performing a control calculation of a difference between the measured value of temperature Th3 of bottom surface 5b2 and the target value. Then, feedback control unit 120 generates control signal CSd for controlling power supply 15ad such that supplied power PWRd thus calculated is provided to second coil 15d.

Until each of temperatures Th1 and Th3 reaches a range where it can be measured by each of pyrometers 9a and 9c, however, the feedback control based on the measured temperature value cannot be performed, and therefore, each of supplied powers PWRu and PWRd is controlled to be predetermined power.

[Second Step (S22)]

In the second step (S22), the control of the power supplied to first coil 15u is switched from the feedback control to the constant power control. The power supplied to first coil 15u in the second step (S22) is determined by calculation based on the power supplied to first coil 15u in the first step (S21). It is noted that the power supplied to second coil 15d continues to be feedback controlled during crystal growth. Therefore, attention will be focused on the control of the power supplied to first coil 15u, which will be described low.

The switching of the control of first coil 15u is basically the same as the switching of the control of the resistive heaters according to the sixth embodiment. That is, the switching of the control of first coil 15u can be explained by replacing power PWR1 supplied to upper resistive heater 1 shown in FIG. 27 by power PWRu supplied to first coil 15u.

In this variation, too, in a manner similar to the sixth variation, feedback control unit 120 performs the feedback control of power PWRu supplied to first coil 15u during execution of the temperature increase in crucible 5 and the pressure reduction in crucible 5 (between time t0 and time t3). Then, when the pressure reduction in chamber 6 is completed and crystal growth starts at time t3, feedback control unit 120 performs the feedback control of supplied power PWRu until time t8 when prescribed time period TP2 elapses since time t3.

During this time period TP2, in time period TP1 from time t7 after time 13 to time t8, constant power control unit 122a obtains data indicative of supplied power PWRu which has been set by feedback control unit 120 for each prescribed cycle. Then, after a lapse of time period TP1, constant power control unit 122a determines set value Pset of supplied power PWRu by calculation by performing statistical processing of the plurality of pieces of data obtained during time period TP1.

Constant power control unit 122a generates control signal CSu for controlling power supply 15au such that power is supplied to first coil 15u in accordance with set value Pset thus determined by calculation. Consequently, the control of the power supplied to first coil 15u is switched from the feedback control to the constant power control. The constant power control is performed during a period from time t8 to at least time t4 when the silicon carbide single crystal growth is completed.

After the switching to the constant power control, constant power Pset independent of measured temperature value Th1 from upper pyrometer 9a is supplied to first coil 15u. Accordingly, even when it has become difficult to measure the temperature of top surface 5a1 due to the occurrence of blockage of opening 4b3 during execution of the constant power control, the constant power in accordance with set value Pset continues to be supplied to first coil 15u, thus allowing the temperature of top surface 5a1 to be maintained at temperature A1.

<Eighth Variation>

(Device of Manufacturing Silicon Carbide Single Crystal)

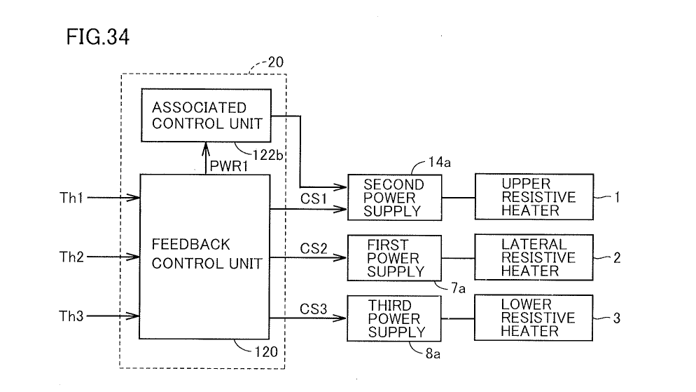

Next, an eighth variation of the device of manufacturing a silicon carbide single crystal according to this embodiment is described. The device of manufacturing a silicon carbide single crystal according to the eighth variation basically has the same configuration as that of manufacturing device 100 shown in FIGS. 19 to 23. The device of manufacturing a silicon carbide single crystal according to this variation, however, is different from the manufacturing device shown in FIGS. 19 to 23 mainly in that it includes an associated control unit 122b (FIG. 34) instead of constant power control unit 122a (FIG. 23). Thus, the same or corresponding parts are designated by the same signs and the same description will not be repeated.

As shown in FIG. 34, controller 20 includes feedback control unit 120 and associated control unit 122b. Feedback control unit 120 receives a measured value of temperature Th1 of top surface 5a1 from upper pyrometer 9a, receives a measured value of temperature Th2 of side surface 5b1 from lateral pyrometer 9b, and receives a measured value of temperature Th3 of bottom surface 5b2 from lower pyrometer 9c. Feedback control unit 120 feedback controls the power supplied to each of upper resistive heater 1, lateral resistive heater 2 and lower resistive heater 3 such that each of the measured values of temperatures Th1, Th2 and Th3 attains to its target value.

Controller 20 is also configured to be able to perform, in addition to the feedback control, associated control where the power supplied to upper resistive heater 1 is controlled to be associated with the power supplied to lateral resistive heater 2. In the step of growing a silicon carbide single crystal (S20: FIG. 24), controller 20 switches the control of the power supplied to upper resistive heater 1 from the feedback control to the associated control. Consequently, “complete feedback control” where the powers supplied to upper resistive heater 1, lateral resistive heater 2 and lower resistive heater 3 are feedback controlled is switched to “partial feedback control” where only the powers supplied to lateral resistive heater 2 and lower resistive heater 3 are feedback controlled. The details of the switching from the complete feedback control to the partial feedback control will be described later.

(Method of Manufacturing Silicon Carbide Single Crystal)

Next, a method of manufacturing a silicon carbide single crystal according to this variation is described. The method of manufacturing a silicon carbide single crystal according to this variation is basically the same as the method of manufacturing a silicon carbide single crystal according to the third variation. The method of manufacturing a silicon carbide single crystal according to this variation, however, is different from the method of manufacturing a silicon carbide single crystal according to the third variation mainly in terms of how to control the power in the crystal growth step (S20).

[Preparation Step (S10)]

As shown in FIG. 24, the method of manufacturing a silicon carbide single crystal according to this variation includes the preparation step (S10) and the crystal growth step (S20). The preparation step (S10) is performed in a manner similar to the preparation step (S10) in FIG. 8. For example, device 100 of manufacturing a silicon carbide single crystal shown in FIGS. 19 to 22 and 34 is prepared. Then, silicon carbide source material 12 and seed crystal 11 are disposed in crucible 5 (see FIG. 25). [Crystal Growth Step (S20)]

In the crystal growth step (S20), power is supplied to upper resistive heater 1, lateral resistive heater 2 and lower resistive heater 3 to heat crucible 5, to sublimate silicon carbide source material 12 to thereby grow a silicon carbide single crystal on surface 11b of seed crystal 11.

[Control of Power to Resistive Heaters]

The temperature control of crucible 5 in the crystal growth step (S20) described above is implemented by controlling the power supplied to each of upper resistive heater 1, lateral resistive heater 2 and lower resistive heater 3. The control of the power supplied to the resistive heaters in the crystal growth step (S20) is now described.

The crystal growth step (S20) includes the first step (S21: FIG. 24) in which the powers supplied to a first heating unit and a second heating unit, respectively, are feedback controlled based on the temperatures of crucible 5 measured by a first pyrometer and a second pyrometer, respectively, and the second step (S22: FIG. 24) in which the power supplied to the second heating unit is feedback controlled based on the temperature of crucible 5 measured by the second pyrometer, and the power supplied to the first heating unit is controlled to be associated with the power supplied to the second heating unit. That is, the complete feedback control is performed in the first step (S21), and the partial feedback control is performed in the second step (S22).

In this variation, as one embodiment of the first step (S21), the powers supplied to upper resistive heater 1, lateral resistive heater 2 and lower resistive heater 3, respectively, are feedback controlled based on the temperatures of crucible 5 measured by pyrometers 9a, 9b and 9c, respectively. In addition, as one embodiment of the second step (S22), the powers supplied to lateral resistive heater 2 and lower resistive heater 3, respectively, are feedback controlled based on the temperatures of crucible 5 measured by lateral pyrometer 9b and lower pyrometer 9c, respectively, and the power supplied to upper resistive heater 1 is controlled to be associated with the power supplied to lateral resistive heater 2.

[First Step (S21)]

In the first step (S21), supplied powers PWR1, PWR2 and PWR3 are feedback controlled such that the measured values of temperatures Th1, Th2 and Th3 agree with their target values, respectively. Such feedback control is implemented by feedback control unit 120 of controller 20 (see FIG. 34).

Specifically, feedback control unit 120 calculates power PWR1 supplied to upper resistive heater 1 by performing a control calculation of a difference between the measured value of temperature Th1 of top surface 5a1 and the target value for each control cycle. Then, feedback control unit 120 generates control signal CS1 for controlling second power supply 14a such that supplied power PWR1 thus calculated is provided to upper resistive heater 1. Feedback control unit 120 calculates power PWR2 supplied to lateral resistive heater 2 by performing a control calculation of a difference between the measured value of temperature Th2 of side surface 5b1 and the target value. Then, feedback control unit 120 generates control signal CS2 for controlling first power supply 7a such that supplied power PWR2 thus calculated is provided to lateral resistive heater 2. Feedback control unit 120 calculates power PWR3 supplied to lower resistive heater 3 by performing a control calculation of a difference between the measured value of temperature Th3 of bottom surface 5b2 and the target value. Then, feedback control unit 120 generates control signal CS3 for controlling third power supply 8a such that supplied power PWR3 thus calculated is provided to lower resistive heater 3.

Until each of temperatures Th1, Th2 and Th3 reaches a range where it can be measured by each of pyrometers 9a, 9b and 9c, however, the feedback control based on the measured temperature value cannot be performed, and therefore, each of supplied powers PWR1, PWR2 and PWR3 is controlled to be predetermined power.

[Second Step (S22)]

In the second step (S22), the control of the power supplied to upper resistive heater 1 is switched from the feedback control to the associated control. The power supplied to upper resistive heater 1 in the second step (S22) is determined by calculation based on a ratio between the power supplied to upper resistive heater 1 and the power supplied to lateral resistive heater 2 in the first step (S21), and the power supplied to lateral resistive heater 2 in the second step (S22). It is noted that the power supplied to lateral resistive heater 2 and the power supplied to lower resistive heater 3 continue to be feedback controlled during the crystal growth. Therefore, attention will be focused on the control of the power supplied to upper resistive heater 1, which will be described low.

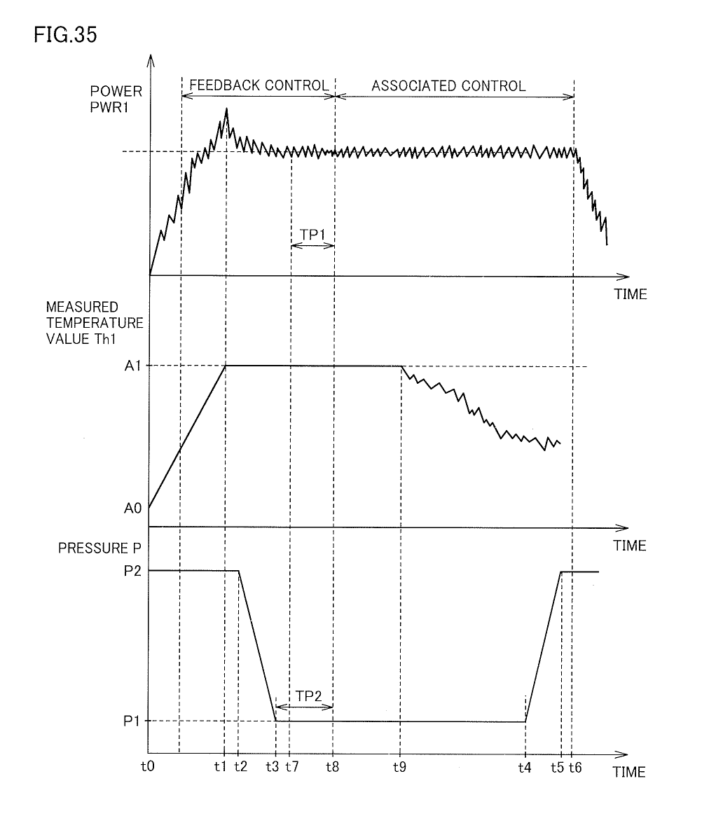

FIG. 35 is a diagram showing temporal variation in power PWR1 supplied to upper resistive heater 1, measured value Th1 of the temperature of top surface 5a1 from upper pyrometer 9a, and the pressure in chamber 6.

As shown in FIG. 35, during a temperature increase process between time t0 and time t1, measured temperature value Th1 from upper pyrometer 9a increases from temperature A0 to temperature A1. In the temperature increase process, feedback control unit 120 of controller 20 performs the feedback control of power PWR1 supplied to upper resistive heater 1 such that measured temperature value Th1 agrees with the target value. Feedback control unit 120 starts performing the feedback control when measured temperature value Th1 reaches the range where it can be measured by upper pyrometer 9a.

After the temperature increase is completed at time t1, feedback control unit 120 performs the feedback control of supplied power PWR1 in order to maintain temperature Th1 of top surface 5a1 at temperature A1. That is, when a difference occurs between measured temperature value Th1 and temperature A1 after time t1, supplied power PWR1 is increased or decreased to eliminate the difference, so that measured temperature value Th1 is maintained at temperature A1. The feedback control of supplied power PWR1 is performed also during execution of the pressure reduction in crucible 5. After the pressure in chamber 6 reaches pressure P1 at time t3, a silicon carbide single crystal grows on surface 11b of seed crystal 11 between time t3 and time t4 during which the pressure is maintained at pressure P1.

Feedback control unit 120 performs the feedback control of supplied power PWR1 until time t8 when prescribed time period TP2 elapses since time t3. During this time period TP2, associated control unit 122b of controller 20 (see FIG. 34) obtains data indicative of supplied power PWR1 which has been set by feedback control unit 120. Associated control unit 122b also obtains data indicative of supplied power PWR2 which has been set by feedback control unit 120. It is noted that the “data indicative of supplied power PWR1” may be a control command of supplied power PWR1 generated by feedback control unit 120, or may be an actual value of power supplied to upper resistive heater 1 from second power supply 14a. Likewise, the “data indicative of supplied power PWR2” may be a control command of supplied power PWR2 generated by feedback control unit 120, or may be an actual value of power supplied to lateral resistive heater 2 from first power supply 7a.

Specifically, during time period TP1 from time t7 after time t3 to time t8, associated control unit 122b obtains the data indicative of supplied power PWR1 and the data indicative of supplied power PWR2 and stores the data in the memory region for each prescribed cycle. It is preferred that time period TP1 start after the condition in crucible 5 has been stabilized after completion of the pressure reduction in chamber 6. For example, time t7 when time period TP1 starts is set to a timing at which about one hour elapses since time t3 when the pressure reduction was completed.

The length of time period TP1 is set, for example, to one hour or more and five hours or less. A cycle in which associated control unit 122b obtains the data during time period TP1 is set, for example, to about 10 to 60 seconds. If the length of time period TP1 is set to one hour and the cycle in which the data is obtained is set to 10 seconds as an example, then 360 pieces of data are obtained during time period TP1.

After a lapse of time period TP1, associated control unit 122b determines a ratio R12 between supplied power PWR1 and supplied power PWR2 (=PWR1/PWR2) by calculation from the plurality of pieces of data obtained during time period TP1. Specifically, associated control unit 122b determines ratio R12 by calculation by performing statistical processing of the plurality of pieces of data. For example, associated control unit 122b determines by calculation a ratio R12(i) between supplied power PWR1(i) and supplied power PWR2(i) obtained during an i^{th} (i being an integer of 1 or more and n or less) cycle. Then, associated control unit 122b determines by calculation an average value of a plurality of ratios R12(1) to R12(n) determined by calculation to correspond to the first cycle to an n^{th} cycle, respectively.

As the statistical processing of the plurality of pieces of data, processing of determining a median value of the plurality of ratios R2(1) to R12(n) by calculation, processing of determining a mode value of the plurality of ratios R12(1) to R12(n) by calculation or the like may be executed, in addition to the processing of determining an average value of the plurality of ratios R12(1) to R12(n) by calculation. In the processing of determining an average value by calculation, the plurality of ratios R12(1) to R12(n) from which abnormal values have been excluded may be averaged. For example, the pieces of data in the top 10% or higher and the pieces of data in the bottom 10% or lower of a distribution of the plurality of ratios R12(1) to R12(n) may be excluded as abnormal values.

Alternatively, an average value (or a median value or a mode value) of a plurality of pieces of data indicative of supplied power PWR1 and an average value (or a median value or a mode value) of a plurality of pieces of data indicative of supplied power PWR2 may be determined by calculation, to determine by calculation ratio R12 between the average value of supplied power PWR1 and average value of supplied power PWR2 thus determined by calculation.

Once ratio R12 is determined by calculation, associated control unit 122b controls supplied power PWR1 such that supplied power PWR1 is associated with supplied power PWR2 while maintaining ratio R12. Specifically, associated control unit 122b obtains the data indicative of supplied power PWR2 from feedback control unit 120 for each prescribed cycle. Associated control unit 122b determines supplied power PWR1 by calculation by multiplying supplied power PWR2 by ratio R12 (PWR1=PWR2×R12).

Associated control unit 122b generates control signal CS1 for controlling second power supply 14a such that power is supplied to upper resistive heater 1 in accordance with supplied power PWR1 thus determined by calculation. Consequently, the control of the power supplied to upper resistive heater 1 is switched from the feedback control to the associated control. The associated control is performed during a period from time t8 to time t6 when the heating of crucible 5 is stopped. That is, the associated control is performed during a period from time t8 to at least time t4 when the silicon carbide single crystal growth is completed.

After the switching to the associated control, power independent of measured temperature value Th1 from upper pyrometer 9a is supplied to upper resistive heater 1. This power is associated with supplied power PWR2 feedback controlled in order to maintain the temperature of side surface 5b1 at temperature A2, while ratio R12 is maintained. In other words, supplied power PWR1 is capable of maintaining top surface 5a1 at temperature A1 at which seed crystal 11 recrystallizes. Accordingly, measured temperature value Th1 is maintained at temperature A1 after time t8 as well.

Here, it is assumed that it has become difficult to measure the temperature of top surface 5a1 due to the occurrence of blockage of opening 4a3 at time t9 during execution of the associated control. Measured temperature value Th1 from upper pyrometer 9a varies as shown in FIG. 35, resulting in difficulty for controller 20 to know the actual temperature of top surface 5a1. According to this variation, even in such a case, the power associated with the power supplied to lateral resistive heater 2 continues to be supplied to upper resistive heater 1, thus allowing the temperature of top surface 5a1 to be maintained at temperature A1 after time t9 as well. As a result, temperature variation in top surface 5a can be suppressed even after the occurrence of blockage of opening 4a3 due to the recrystallized silicon carbide.

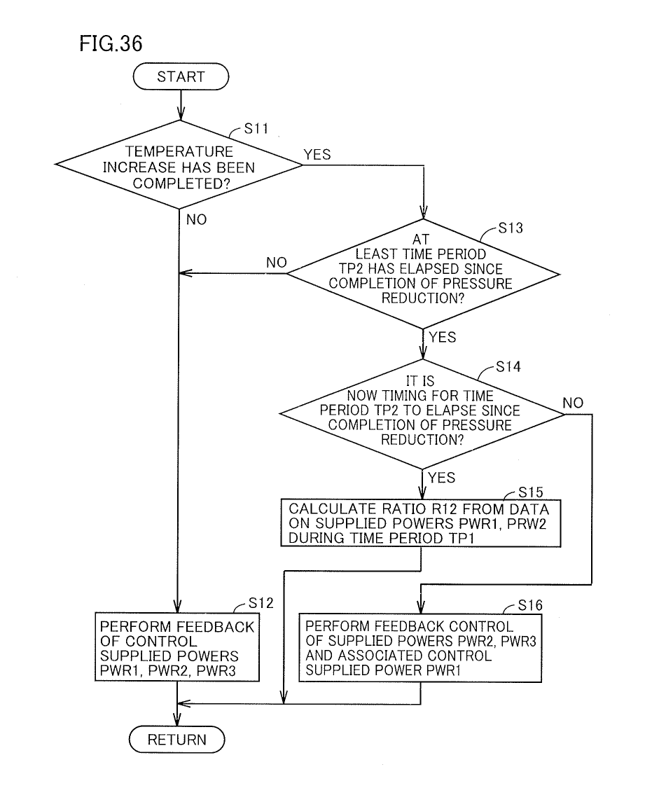

FIG. 36 is a flowchart showing a control process procedure executed by controller 20 in order to implement the switching of the control of upper resistive heater 1. The control process shown in FIG. 36 is repeatedly executed for each control cycle.

As shown in FIG. 36, first, in step S11, it is determined whether the temperature increase in silicon carbide source material 12 and seed crystal 11 has been completed or not. If it is determined that the temperature increase has not been completed (NO determination in S11), in step S12, the feedback control of supplied powers PWR1, PWR2 and PWR3 based on the measured values of temperatures Th1, Th2 and Th3 is performed (complete feedback control).

If it is determined that the temperature increase has been completed (YES determination in S11), on the other hand, in step S13, it is determined whether at least time period TP2 has elapsed or not since the time when the pressure reduction in chamber 6 was completed. Time period TP2 is set, as shown in FIG. 35, to a time from time t3 when the pressure reduction is completed to time t8 when time period TP1 during which the data indicative of supplied power PWR1 is obtained ends.

If at least time period TP2 has not elapsed since the time when the pressure reduction was completed (NO determination in S13), in step S12, the feedback control of supplied powers PWR1, PWR2 and PWR3 is performed. If at least time period TP2 has elapsed since the time when the pressure reduction was completed (YES determination in S13), the process proceeds to step S14 where it is determined whether it is now timing for time period TP2 to elapse or not since the time when the pressure reduction was completed. If it is determined that it is now timing for time period TP2 to elapse since the time when the pressure reduction was completed (YES determination in S14), in step S15, ratio R12 between supplied power PWR1 and supplied power PWR2 is determined by calculation from the plurality of pieces of data obtained during time period TP1.

If it is determined that the timing for time period TP2 to elapse since the time when the pressure reduction was completed has elapsed (NO determination in S14), on the other hand, in step S16, the associated control is performed on power PWR1 supplied to upper resistive heater 1. It is noted that power PWR2 supplied to lateral resistive heater 2 and power PWR3 supplied to lower resistive heater 3 continue to be feedback controlled (partial feedback control).

Returning to FIG. 35, between time t4 and time t5, the pressure in chamber 6 increases from pressure P1 to pressure P2. Because of the pressure increase in chamber 6, the sublimation of silicon carbide source material 12 is suppressed. The silicon carbide single crystal growth is thus substantially completed. At time t6, the heating of crucible 5 is stopped to cool crucible 5. After the temperature of crucible 5 approaches the room temperature, silicon carbide single crystal 30 is removed from crucible 5 (see FIG. 29).

<Ninth Variation>

Although the eighth variation has described the configuration where the power supplied to upper resistive heater 1 is associated with the power supplied to lateral resistive heater 2 in the second step (S22: FIG. 24), the power supplied to upper resistive heater 1 may be associated with the power supplied to lower resistive heater 3. That is, the power supplied to upper resistive heater 1 in the second step (S22) is determined by calculation based on a ratio between the power supplied to upper resistive heater 1 and the power supplied to lower resistive heater 3 in the first step (S21), and the power supplied to lower resistive heater 3 in the second step (S22).

Specifically, in the crystal growth step (S20), the power supplied to each of upper resistive heater 1, lateral resistive heater 2 and lower resistive heater 3 is feedback controlled by feedback control unit 120 during time period TP1. During time period TP1, associated control unit 122b obtains data indicative of supplied power PWR1 and data indicative of supplied power PWR3 and stores the data in the memory region for each prescribed cycle. Then, after a lapse of time period TP1, associated control unit 122b determines a ratio R13 between supplied power PWR1 and supplied power PWR3 (=PWR1/PWR3) by calculation by performing statistical processing of the data obtained during time period TP1.

Then, during a period from time t8 after the lapse of time period TP1 to at least time t4 when the silicon carbide single crystal growth is completed, the power supplied to each of lateral resistive heater 2 and lower resistive heater 3 is feedback controlled. Meanwhile, power associated with supplied power PWR3 feedback controlled in order to maintain the temperature of bottom surface 5b2 at temperature A3 while ratio R13 is maintained is supplied to upper resistive heater 1.

<Tenth Variation>

Although the switching from the complete feedback control to the partial feedback control is done once in the crystal growth step (S20) in the eighth variation, the switching may be done a plurality of times. That is, the first step (S21) in which the complete feedback control is performed and the second step (S22) in which the partial feedback control is performed may be alternately repeated during crystal growth.

For example, controller 20 monitors measured temperature value Th1 from upper pyrometer 9a during execution of the second step (S22), and determines whether measured temperature value Th1 is within a range of ±10% of temperature A1 or not. If it is determined that measured temperature value Th1 is within that range, controller 20 proceeds to the first step (S21) to switch the control of the power to upper resistive heater 1 from the associated control to the feedback control. Then, after the feedback control is performed again for a prescribed time period, ratio R12 is determined by calculation based on the data indicative of supplied power PWR1 and the data indicative of supplied power PWR2 obtained during this prescribed time period. Consequently, in the second step (S22) subsequent to this first step (S21), power associated with the power supplied to lateral resistive heater 2 while ratio R12 determined by calculation in the immediately preceding first step (S21) is maintained is supplied to upper resistive heater 1.

By alternately repeating the feedback control and the associated control in this manner, the ratio between the power supplied to upper resistive heater 1 and the power supplied to lateral resistive heater 2 during execution of the associated control is updated to ratio R12 in the immediately preceding feedback control. Consequently, during crystal growth, upper resistive heater 1 can continue to generate an amount of heat for maintaining the temperature of top surface 5a1 at temperature A1.

<Eleventh Variation>

(Device of Manufacturing Silicon Carbide Single Crystal)

As shown in FIG. 32, device 112 of manufacturing a silicon carbide single crystal according to this variation basically has the same configuration as that of manufacturing device 112 according to the seventh variation. The device of manufacturing a silicon carbide single crystal according to this variation, however, is different from the manufacturing device according to the seventh variation mainly in that it includes associated control unit 122b (FIG. 34) instead of constant power control unit 122a (FIG. 23). Thus, the same or corresponding parts are designated by the same signs and the same description will not be repeated.

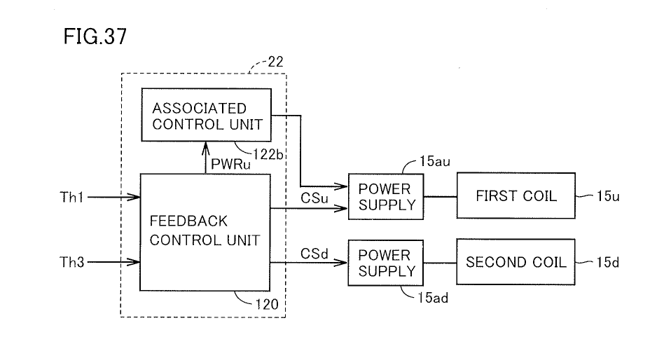

FIG. 37 is a functional block diagram illustrating the temperature control of crucible 5 in device 112 of manufacturing a silicon carbide single crystal according to this variation. As shown in FIG. 37, controller 22 includes feedback control unit 120 and associated control unit 122b.

Feedback control unit 120 receives a measured value of temperature Th1 of top surface 5a1 from upper pyrometer 9a, and receives a measured value of temperature Th3 of bottom surface 5b2 from lower pyrometer 9c. Feedback control unit 120 feedback controls the power supplied to each of first coil 15u and second coil 15d such that each of the measured values of temperatures Th1 and Th3 attains to its target value.

Associated control unit 122b is configured to be able to perform associated control where the power supplied to first coil 15u is associated with the power supplied to second coil 15d. In the step of growing a silicon carbide single crystal (S20: FIG. 24), controller 22 switches the control of the power supplied to first coil 15u from the feedback control to the associated control.

<Method of Manufacturing Silicon Carbide Single Crystal>

Next, a method of manufacturing a silicon carbide single crystal according to this variation is described. The method of manufacturing a silicon carbide single crystal according to this variation is basically the same as the method of manufacturing a silicon carbide single crystal according to the seventh variation. The method of manufacturing a silicon carbide single crystal according to this variation, however, is different from the method of manufacturing a silicon carbide single crystal according to the seventh variation mainly in terms of how to control the power in the crystal growth step (S20).

[Control of Power Supplied to High-Frequency Heating Coil]

In the crystal growth step (S20), power is supplied to first coil 15u and second coil 15d to heat crucible 5, to sublimate silicon carbide source material 12 to thereby grow a silicon carbide single crystal on surface 11b of seed crystal 11.

The crystal growth step (S20) includes the first step (S21) and the second step (S22). In this variation, as one embodiment of the first step (S21), the powers supplied to first coil 15u and second coil 15d, respectively, are feedback controlled based on the temperatures of crucible 5 measured by upper pyrometer 9a and lower pyrometer 9c, respectively. In addition, as one embodiment of the second step (S22), the power supplied to second coil 15d is feedback controlled based on the temperature of crucible 5 measured by lower pyrometer 9c, and the power supplied to first coil 15u is controlled to be associated with the power supplied to second coil 15d.

[First Step (S21)]

In the first step (S21), feedback control where the powers supplied to first coil 15u and second coil 15d are increased or decreased is performed such that the measured values of temperatures Th1 and Th3 agree with their target values, respectively. Such complete feedback control is implemented by feedback control unit 120 of controller 22 (see FIG. 37).

Specifically, feedback control unit 120 calculates power PWRu supplied to first coil 15u by performing a control calculation of a difference between the measured value of temperature Th1 of top surface 5a1 and the target value for each control cycle. Then, feedback control unit 120 generates control signal CSu for controlling power supply 15au such that supplied power PWRu thus calculated is provided to first coil 15u. Feedback control unit 120 also calculates power PWRd supplied to second coil 15d by performing a control calculation of a difference between the measured value of temperature Th3 of bottom surface 5b2 and the target value. Then, feedback control unit 120 generates control signal CSd for controlling power supply 15ad such that supplied power PWRd thus calculated is provided to second coil 15d.

Until each of temperatures Th1 and Th3 reaches a range where it can be measured by each of pyrometers 9a and 9c, however, the feedback control based on the measured temperature value cannot be performed, and therefore, each of supplied powers PWRu and PWRd is controlled to be predetermined power.

[Second Step (S22)]

In the second step (S22), the control of the power supplied to first coil 15u is switched from the feedback control to the associated control. The power supplied to first coil 15u in the second step (S22) is determined by calculation based on a ratio between the power supplied to first coil 15u and the power supplied to second coil 15d in the first step (S21), and the power supplied to second coil 15d in the second step (S22). It is noted that the power supplied to second coil 15d continues to be feedback controlled during crystal growth. Therefore, attention will be focused on the control of the power supplied to first coil 15u, which will be described low.

The switching of the control of first coil 15u is basically the same as the switching of the control of upper resistive heater 1 according to the eighth variation. That is, the switching of the control of first coil 15u can be explained by replacing power PWR1 supplied to upper resistive heater 1 shown in FIG. 35 by power PWRu supplied to first coil 15u, and by replacing power PWR2 supplied to lateral resistive heater 2 by power PWRd supplied to second coil 15d.

In this variation, too, in a manner similar to the eighth variation, feedback control unit 120 performs the feedback control of power PWRu supplied to first coil 15u during execution of the temperature increase in crucible 5 and the pressure reduction in crucible 5 (between time t0 and time t3). Then, when the pressure reduction in chamber 6 is completed and the crystal growth step (S20) starts at time t3, feedback control unit 120 performs the feedback control of supplied power PWRu until time t8 when prescribed time period TP2 elapses since time t3.

During this time period TP2, in time period TP1 from time t7 after time t3 to time t8, associated control unit 122b obtains data indicative of supplied power PWRu and data indicative of supplied power PWRd which has been set by feedback control unit 120 and stores the data in the memory region for each prescribed cycle. Then, after a lapse of time period TP1, associated control unit 122b determines a ratio Rud between supplied power PWRu and supplied power PWRd (=PWRu/PWRd) by calculation by performing statistical processing of the plurality of pieces of data obtained during time period TP1.

Then, during a period from time t8 after the lapse of time period TP1 to at least time t4 when the silicon carbide single crystal growth is completed, the power supplied to second coil 15d is feedback controlled. Meanwhile, control signal CSu for controlling power supply 15au is generated such that power associated with the power supplied to second coil 15d is supplied to first coil 15u. Specifically, associated control unit 122b obtains the data indicative of supplied power PWRu from feedback control unit 120 for each prescribed cycle, and determines supplied power PWRd by calculation by multiplying supplied power PWRu by ratio Rud (PWRd=PWRu×Rud). Consequently, the control of the power supplied to first coil 15u is switched from the feedback control to the associated control. The associated control is performed during a period from time t8 to at least time t4 when the silicon carbide single crystal growth is completed.

After the switching to the associated control, power associated with supplied power PWRd feedback controlled in order to maintain the temperature of bottom surface 5b2 at temperature A3 while ratio Rud is maintained is supplied to first coil 15u. Supplied power PWRu is capable of maintaining top surface 5a1 at temperature A1 at which seed crystal 11 recrystallizes. Accordingly, measured temperature value Th1 is maintained at temperature A1 after time t8 as well.

Next, a function and effect of the method of manufacturing a silicon carbide single crystal according to this embodiment will be described.

In accordance with the method of manufacturing a silicon carbide single crystal according to this embodiment, the heater is provided with third opening 2e in communication with each of first opening 4b3 provided in heat insulator 4 and second opening 6b provided in chamber 6. Thus, an outer surface of crucible 5 can be partially exposed to the outside of chamber 6 through the first to third openings. Accordingly, the temperature of crucible 5 can be directly measured, with pyrometer 9b disposed outside chamber 6 in a position facing the outer surface of crucible 5. As a result, a temperature gradient in crucible 5 during crystal growth can be controlled without being affected by a change in shape of lateral resistive heater 2.

In accordance with the method of manufacturing a silicon carbide single crystal according to this embodiment, third opening 2e may have a line-symmetrical shape with axis AX passing through first slit 2f1 or second slit 2f2 as a symmetry axis. According to this method, the occurrence of a difference in resistance value of lateral resistive heater 2 between opposing portions surrounding third opening 2e can be avoided, thereby preventing third opening 2e from creating an imbalance in the amount of heat generation in lateral resistive heater 2 which is an annular body.

Further, in accordance with the method of manufacturing a silicon carbide single crystal according to this embodiment, device 100 may further include first terminal 7t1 having one end electrically connected to one pole of first power supply 7a and the other end connected to upper end surface 2a or lower end surface 2b, and second terminal 7t2 having one end electrically connected to the other pole of first power supply 7a and the other end connected to upper end surface 2a or lower end surface 2b. First terminal 7t1 and second terminal 7t2 may be disposed in positions facing each other with the central axis of the annular body therebetween. Third opening 2e may be disposed in a position partially overlapping with the other end of first terminal 7t1 or second terminal 7t2 when viewed from the upper end surface. According to this method, the occurrence of a difference in resistance value between a pair of resistive elements connected in parallel between first terminal 7t1 and second terminal 7t2 can be prevented on an equivalent circuit formed of the resistive elements. Thus, a balance in the amount of heat generation can be maintained between the pair of resistive elements, thereby preventing third opening 2e from creating an imbalance in the amount of heat generation in lateral resistive heater 2.

Further, in accordance with the method of manufacturing a silicon carbide single crystal according to this embodiment, the control of the power supplied to lateral resistive heater 2 in the step of growing a silicon carbide single crystal is the feedback control based on the difference between the measured value of the temperature of crucible 5 and the target value, then switched to the constant power control where the power is fixed to constant power. The power supplied to lateral resistive heater 2 during the constant power control is determined by calculation from the power feedback controlled in the first step. Consequently, also in the second step in which the constant power control is performed, lateral resistive heater 2 can generate an amount of heat for silicon carbide single crystal growth. As a result, during the silicon carbide single crystal growth, even when first opening 4b3 for temperature measurement is blocked due to the recrystallized silicon carbide, the temperature control of crucible 5 can be prevented from becoming unstable.

Further, in accordance with the method of manufacturing a silicon carbide single crystal according to this embodiment, in the first step, the powers supplied to upper resistive heater 1, lateral resistive heater 2 and lower resistive heater 3, respectively, may be feedback controlled based on the temperatures of the crucible measured by upper pyrometer 9a, lateral pyrometer 9b and lower pyrometer 9c, respectively. In the second step, the powers supplied to lateral resistive heater 2 and lower resistive heater 3, respectively, may be feedback controlled based on the temperatures of crucible 5 measured by lateral pyrometer 9b and lower pyrometer 9c, respectively, and the power supplied to upper resistive heater 1 may be controlled to be constant power. The power supplied to upper resistive heater 1 in the second step may be determined by calculation based on the power supplied to upper resistive heater 1 in the first step. During the silicon carbide single crystal growth, the temperature of crucible 5 decreases in the direction from bottom surface 5b2 toward top surface 5a1, and therefore, the source material gas diffused to the outside of crucible 5 is transferred in the direction toward top surface 5a1 in accordance with this temperature gradient. Thus, the source material gas tends to recrystallize near opening 4a3 for temperature measurement disposed to face top surface 5a1. According to this embodiment, even when opening 4a3 for temperature measurement disposed to face top surface 5a1 is blocked, upper resistive heater 1 can generate an amount of heat for maintaining the temperature of top surface 5a1 at the target value, thereby preventing the temperature control of crucible 5 during the silicon carbide single crystal growth from becoming unstable.

Further, in accordance with the method of manufacturing a silicon carbide single crystal according to this embodiment, in the first step, the powers supplied to upper resistive heater 1, lateral resistive heater 2 and lower resistive heater 3, respectively, may be feedback controlled based on the temperatures of crucible 5 measured by upper pyrometer 9a, lateral pyrometer 9b and lower pyrometer 9c, respectively. In the second step, the powers supplied to upper resistive heater 1 and lower resistive heater 3, respectively, may be feedback controlled based on the temperatures of crucible 5 measured by upper pyrometer 9a and lower pyrometer 9c, respectively, and the power supplied to lateral resistive heater 2 may be controlled to be constant power. The power supplied to lateral resistive heater 2 in the second step may be determined by calculation based on the power supplied to lateral resistive heater 2 in the first step. While the source material gas diffused to the outside of crucible 5 is transferred in the direction toward top surface 5a1, the source material gas may recrystallize also near first opening 4b3 for temperature measurement disposed to face side surface 5b1. In accordance with this method of manufacturing a silicon carbide single crystal, even when first opening 4b3 for temperature measurement disposed to face side surface 5b1 is blocked, lateral resistive heater 2 can generate an amount of heat for maintaining the temperature of side surface 5b1 at the target value, thereby preventing the temperature control of crucible 5 during the silicon carbide single crystal growth from becoming unstable.

Further, in accordance with the method of manufacturing a silicon carbide single crystal according to this embodiment, in the step of growing a silicon carbide single crystal, the pressure reduction in crucible 5 may be carried out during execution of the first step. The power supplied to lateral resistive heater 2 in the second step may be determined by calculation based on the power supplied to lateral resistive heater 2 in the first step after completion of the pressure reduction in crucible 5. Consequently, the power supplied to lateral resistive heater 2 during the constant power control is determined by calculation from the power feedback controlled during a period when a silicon carbide single crystal grows on the surface of the seed crystal. Thus, lateral resistive heater 2 can generate an amount of heat for silicon carbide single crystal growth also during a period when the constant power control is performed, thereby preventing the temperature control of crucible 5 during the silicon carbide single crystal growth from becoming unstable.

Further, in accordance with the method of manufacturing a silicon carbide single crystal according to this embodiment, in the step of growing a silicon carbide single crystal, the control of the power supplied to upper resistive heater 1 is the feedback control based on the difference between the measured value of the temperature of top surface 5a1 and the target value, then switched to the associated control where the power supplied to upper resistive heater 1 is associated with the power supplied to lateral resistive heater 2 or lower resistive heater 3. Consequently, the complete feedback control where the powers supplied to upper resistive heater 1, lateral resistive heater 2 and lower resistive heater 3 are feedback controlled is switched to the partial feedback control where only the powers supplied to lateral resistive heater 2 and lower resistive heater 3 are feedback controlled. The power supplied to upper resistive heater 1 during this partial feedback control is controlled such that a ratio between the power supplied to upper resistive heater 1 and the power supplied to lateral resistive heater 2 or lower resistive heater 3 during the complete feedback control is maintained relative to the power supplied to lateral resistive heater 2 or lower resistive heater 3. Thus, upper resistive heater 1 can generate an amount of heat for maintaining the temperature of top surface 5a1 at the target value also during the period when the partial feedback control is performed. As a result, during the silicon carbide single crystal growth, even when fourth opening 4a3 for temperature measurement disposed to face top surface 5a1 is blocked due to the recrystallized silicon carbide, the temperature control of crucible 5 can be prevented from becoming unstable.

Further, in accordance with the method of manufacturing a silicon carbide single crystal according to this embodiment, during the partial feedback control, the power supplied to upper resistive heater 1 is controlled such that a ratio between the power supplied to upper resistive heater 1 and the power supplied to lateral resistive heater 2 during the complete feedback control is maintained relative to the power supplied to lateral resistive heater 2. Thus, even when fourth opening 4a3 for temperature measurement disposed to face top surface 5a1 is blocked, upper resistive heater 1 can generate an amount of heat for maintaining the temperature of top surface 5a1 at the target value, thereby preventing the temperature control of the crucible during the silicon carbide single crystal growth from becoming unstable.

Further, in accordance with the method of manufacturing a silicon carbide single crystal according to this embodiment, during the partial feedback control, the power supplied to upper resistive heater 1 is controlled such that a ratio between the power supplied to upper resistive heater 1 and the power supplied to lower resistive heater 3 during the complete feedback control is maintained relative to the power supplied to lower resistive heater 3. Thus, even when fourth opening 4a3 for temperature measurement disposed to face top surface 5a1 is blocked, upper resistive heater 1 can generate an amount of heat for maintaining the temperature of top surface 5a1 at the target value, thereby preventing the temperature control of crucible 5 during the silicon carbide single crystal growth from becoming unstable.

Further, in accordance with the method of manufacturing a silicon carbide single crystal according to this embodiment, in the step of growing a silicon carbide single crystal, the pressure reduction in crucible 5 may be carried out during execution of the first step. The power supplied to upper resistive heater 1 in the second step may be determined by calculation based on a ratio between the power supplied to upper resistive heater 1 and the power supplied to lateral resistive heater 2 or lower resistive heater 3 in the first step after completion of the pressure reduction in crucible 5, and the power supplied to lateral resistive heater 2 or lower resistive heater 3 in the second step. Consequently, the ratio between the power supplied to upper resistive heater 1 and the power supplied to lateral resistive heater 2 or lower resistive heater 3 during the partial feedback control is determined by calculation from the power feedback controlled during a period when a silicon carbide single crystal grows on the surface of the seed crystal. Thus, upper resistive heater 1 can generate an amount of heat for silicon carbide single crystal growth also during a period when the associated control is performed, thereby preventing the temperature control of crucible 5 during the silicon carbide single crystal growth from becoming unstable.

<Aspects>

The foregoing description includes features in the following aspects.

(Aspect 1)

A manufacturing device for manufacturing a silicon carbide single crystal by sublimation, comprising a resistive heater which is an annular body in which a crucible can be disposed, a heat insulator disposed to surround the circumference of the resistive heater, a first terminal having one end electrically connected to one pole of a power supply and the other end connected to an upper end surface or a lower end surface of the annular body, a second terminal having one end electrically connected to the other pole of the power supply and the other end connected to the upper end surface or the lower end surface, the second terminal being disposed in a position facing the first terminal with a central axis of the annular body therebetween, and a chamber that accommodates the resistive heater, the heat insulator, the first terminal and the second terminal, the heat insulator being provided with a first opening in a position facing the resistive heater, the chamber being provided with a second opening in communication with the first opening, the resistive heater having a first slit extending from the upper end surface toward the lower end surface and a second slit extending from the lower end surface toward the upper end surface, the first and second slits being alternately arranged along a circumferential direction, the resistive heater being provided with a third opening penetrating the annular body and being in communication with the first and second openings, the third opening having a line-symmetrical shape with an axis passing through the first slit or the second slit as a symmetry axis, the third opening being disposed in a position at least partially overlapping with the other end of the first terminal or the second terminal when viewed from the upper end surface, the device further comprising a pyrometer disposed outside the chamber, the pyrometer being configured to be able to measure a temperature of the crucible through the first to third openings.

In accordance with this device, the temperature of the crucible can be directly measured through the first to third openings, with the pyrometer disposed outside the chamber in a position facing an outer surface of the crucible. Thus, a temperature gradient in the crucible during crystal growth can be controlled without being affected by a change in shape of the heater. In addition, the third opening can be prevented from creating an imbalance in the amount of heat generation in the annular body forming the heater.

(Aspect 2)

A method of manufacturing a silicon carbide single crystal, comprising the steps of preparing a crucible, a source material disposed in the crucible, a seed crystal disposed in the crucible so as to face the source material, a heating unit provided around the circumference of the crucible, a heat insulator disposed to cover the crucible and provided with an opening in a position facing an outer surface of the crucible, and a pyrometer configured to be able to measure a temperature of the crucible through the opening, and growing a silicon carbide single crystal on the seed crystal by sublimation of the source material by supplying power to the heating unit to heat the crucible, the step of growing a silicon carbide single crystal including a first step in which the power supplied to the heating unit is feedback controlled based on the temperature of the crucible measured by the pyrometer, and a second step in which the power supplied to the heating unit is controlled to be constant power, the power supplied to the heating unit in the second step being determined by calculation based on the power supplied to the heating unit in the first step.

In the method of manufacturing a silicon carbide single crystal according to (Aspect 2) above, the control of the power supplied to the heating unit in the step of growing a silicon carbide single crystal is feedback control based on a difference between a measured value of the temperature of the crucible and a target value, then switched to constant power control where the power is fixed to constant power. The power supplied to the heating unit during the constant power control is determined by calculation from the power feedback controlled in the first step. Consequently, also in the second step in which the constant power control is performed, the heating unit can generate an amount of heat for silicon carbide single crystal growth. As a result, during the silicon carbide single crystal growth, even when the opening for temperature measurement is blocked due to the recrystallized silicon carbide, the temperature control of the crucible can be prevented from becoming unstable.

(Aspect 3)

The method of manufacturing a silicon carbide single crystal according to Aspect 2, wherein the heating unit includes a high-frequency heating coil wound around the circumference of the crucible, in the first step, the power supplied to the high-frequency heating coil is feedback controlled based on the temperature of the crucible measured by the pyrometer, in the second step, the power supplied to the high-frequency heating coil is controlled to be constant power, and the power supplied to the high-frequency heating coil in the second step is determined by calculation based on the power supplied to the high-frequency heating coil in the first step. Consequently, even when the opening for temperature measurement is blocked due to the recrystallized silicon carbide, the high-frequency heating coil can generate an amount of heat for silicon carbide single crystal growth, thereby preventing the temperature control of the crucible during the silicon carbide single crystal growth from becoming unstable.

(Aspect 4)

The method of manufacturing a silicon carbide single crystal according to Aspect 2, wherein the crucible has a top surface, a bottom surface opposite to the top surface, and a tubular side surface located between the top surface and the bottom surface, the heat insulator is provided with the opening in a position facing the top surface, and the pyrometer is configured to be able to measure a temperature of the top surface through the opening. Consequently, even when the opening for temperature measurement disposed to face the top surface is blocked, the high-frequency heating coil can generate an amount of heat for maintaining the temperature of the top surface at the target value, thereby preventing the temperature control of the crucible during the silicon carbide single crystal growth from becoming unstable.

(Aspect 5)

The method of manufacturing a silicon carbide single crystal according to Aspect 2, wherein the crucible has a top surface, a bottom surface opposite to the top surface, and a tubular side surface located between the top surface and the bottom surface, the high-frequency heating coil includes a first coil wound around the circumference of the crucible on the side close to the top surface, and a second coil wound around the circumference of the crucible on the side close to the bottom surface, the heat insulator is provided with the opening in each of a position facing the top surface and a position facing the bottom surface, the pyrometer includes a first pyrometer configured to be able to measure a temperature of the top surface through the opening, and a second pyrometer configured to be able to measure a temperature of the bottom surface through the opening, in the first step, the powers supplied to the first coil and the second coil, respectively, are feedback controlled based on the temperatures of the crucible measured by the first pyrometer and the second pyrometer, respectively, in the second step, the power supplied to the second coil is feedback controlled based on the temperature of the crucible measured by the second pyrometer, and the power supplied to the first coil is controlled to be constant power, and the power supplied to the first coil in the second step is determined by calculation based on the power supplied to the first coil in the first step. Consequently, even when the opening for temperature measurement disposed to face the top surface is blocked, the first coil can generate an amount of heat for maintaining the temperature of the top surface at the target value, thereby preventing the temperature control of the crucible during the silicon carbide single crystal growth from becoming unstable.

(Aspect 6)

A method of manufacturing a silicon carbide single crystal, comprising the steps of preparing a crucible having a top surface, a bottom surface opposite to the top surface, and a tubular side surface located between the top surface and the bottom surface, a source material disposed in the crucible on the side close to the bottom surface, a seed crystal disposed in the crucible on the side close to the top surface so as to face the source material, a first resistive heater provided to face the top surface, a second resistive heater provided to surround the side surface, a third resistive heater provided to face the bottom surface, a heat insulator disposed to cover the first resistive heater, the second resistive heater and the third resistive heater, the heat insulator being provided with a first opening in a position facing the top surface, being provided with a second opening in a position facing the side surface, and being provided with a third opening in a position facing the bottom surface, a first pyrometer configured to be able to measure a temperature of the top surface through the first opening, a second pyrometer configured to be able to measure a temperature of the side surface through the second opening, and a third pyrometer configured to be able to measure a temperature of the bottom surface through the third opening, and growing a silicon carbide single crystal on the seed crystal by sublimation of the source material by supplying power to each of the first resistive heater, the second resistive heater and the third resistive heater to heat the crucible, the step of growing a silicon carbide single crystal including a first step in which the powers supplied to the first resistive heater, the second resistive heater and the third resistive heater, respectively, are feedback controlled based on the temperatures of the crucible measured by the first pyrometer, the second pyrometer and the third pyrometer, respectively, and a second step in which the powers supplied to the second resistive heater and the third resistive heater, respectively, are feedback controlled based on the temperatures of the crucible measured by the second resistive heater and the third resistive heater, respectively, and the power supplied to the first resistive heater is controlled to be constant power, the power supplied to the first resistive heater in the second step being determined by calculation based on the power supplied to the first resistive heater in the first step.

In accordance with the method of manufacturing a silicon carbide single crystal according to (Aspect 6) above, during the silicon carbide single crystal growth, even when the opening for temperature measurement disposed to face the top surface is blocked, the first resistive heater can generate an amount of heat for maintaining the temperature of the top surface at the target value, thereby preventing the temperature control of the crucible from becoming unstable.

(Aspect 7)

A method of manufacturing a silicon carbide single crystal, comprising the steps of preparing a crucible having a top surface, a bottom surface opposite to the top surface, and a tubular side surface located between the top surface and the bottom surface, a source material disposed in the crucible on the side close to the bottom surface, a seed crystal disposed in the crucible on the side close to the top surface so as to face the source material, a first resistive heater provided to face the top surface, a second resistive heater provided to surround the side surface, a third resistive heater provided to face the bottom surface, a heat insulator disposed to cover the first resistive heater, the second resistive heater and the third resistive heater, the heat insulator being provided with a first opening in a position facing the top surface, being provided with a second opening in a position facing the side surface, and being provided with a third opening in a position facing the bottom surface, a first pyrometer configured to be able to measure a temperature of the top surface through the first opening, a second pyrometer configured to be able to measure a temperature of the side surface through the second opening, and a third pyrometer configured to be able to measure a temperature of the bottom surface through the third opening, and growing a silicon carbide single crystal on the seed crystal by sublimation of the source material by supplying power to each of the first resistive heater, the second resistive heater and the third resistive heater to heat the crucible, the step of growing a silicon carbide single crystal including a first step in which the powers supplied to the first resistive heater, the second resistive heater and the third resistive heater, respectively, are feedback controlled based on the temperatures of the crucible measured by the first pyrometer, the second pyrometer and the third pyrometer, respectively, and a second step in which the powers supplied to the first resistive heater and the third resistive heater, respectively, are feedback controlled based on the temperatures of the crucible measured by the first pyrometer and the third resistive heater, respectively, and the power supplied to the second resistive heater is controlled to be constant power, the power supplied to the second resistive heater in the second step being determined by calculation based on the power supplied to the second resistive heater in the first step.

In accordance with the method of manufacturing a silicon carbide single crystal according to (Aspect 7) above, during the silicon carbide single crystal growth, even when the opening for temperature measurement disposed to face the side surface is blocked, the second resistive heater can generate an amount of heat for maintaining the temperature of the side surface at the target value, thereby preventing the temperature control of the crucible from becoming unstable.

(Aspect 8)

A method of manufacturing a silicon carbide single crystal, comprising the steps of preparing a crucible having a top surface, a bottom surface opposite to the top surface, and a tubular side surface located between the top surface and the bottom surface, a source material disposed in the crucible on the side close to the bottom surface, a seed crystal disposed in the crucible on the side close to the top surface so as to face the source material, a first heating unit for heating the top surface, a second heating unit for heating the bottom surface, a heat insulator disposed to cover the crucible, the heat insulator being provided with an opening in each of at least a position facing the top surface and a position facing the bottom surface, a first pyrometer configured to be able to measure a temperature of the top surface through the opening, and a second pyrometer configured to be able to measure a temperature of the bottom surface through the opening, and growing a silicon carbide single crystal on the seed crystal by sublimation of the source material by supplying power to each of the first heating unit and the second heating unit to heat the crucible, the step of growing a silicon carbide single crystal including a first step in which the powers supplied to the first heating unit and the second heating unit, respectively, are feedback controlled based on the temperatures of the crucible measured by the first pyrometer and the second pyrometer, respectively, and a second step in which the power supplied to the second heating unit is feedback controlled based on the temperature of the crucible measured by the second pyrometer, and the power supplied to the first heating unit is controlled to be associated with the power supplied to the second heating unit, the power supplied to the first heating unit in the second step being determined by calculation based on a ratio between the power supplied to the first heating unit and the power supplied to the second heating unit in the first step, and the power supplied to the second heating unit in the second step.

In the method of manufacturing a silicon carbide single crystal according to (Aspect 8) above, in the step of growing a silicon carbide single crystal, the control of the power supplied to the first heating unit is the feedback control based on the difference between the measured value of the temperature of the top surface and the target value, then switched to the associated control where the power supplied to the first heating unit is associated with the power supplied to the second heating unit. Consequently, the complete feedback control where the powers supplied to the first heating unit and the second heating unit are feedback controlled is switched to the partial feedback control where only the power supplied to the second heating unit is feedback controlled. The power supplied to the first heating unit during this partial feedback control is controlled such that a ratio between the power supplied to the first heating unit and the power supplied to the second heating unit during the complete feedback control is maintained relative to the power supplied to the second heating unit. Thus, the first heating unit can generate an amount of heat for maintaining the temperature of the top surface at the target value also during a period when the partial feedback control is performed. As a result, during the silicon carbide single crystal growth, even when the opening for temperature measurement disposed to face the top surface is blocked due to the recrystallized silicon carbide, the temperature control of the crucible can be prevented from becoming unstable.

(Aspect 9)

The method of manufacturing a silicon carbide single crystal according to Aspect 8, wherein the first heating unit includes a first coil wound around the circumference of the crucible on the side close to the top surface, the second heating unit includes a second coil wound around the circumference of the crucible on the side close to the bottom surface, in the first step, the powers supplied to the first coil and the second coil, respectively, are feedback controlled based on the temperatures of the crucible measured by the first pyrometer and the second pyrometer, respectively, in the second step, the power supplied to the second coil is feedback controlled based on the temperature of the crucible measured by the second pyrometer, and the power supplied to the first coil is controlled to be associated with the power supplied to the second coil, and the power supplied to the first coil in the second step is determined by calculation based on a ratio between the power supplied to the first coil and the power supplied to the second coil in the first step, and the power supplied to the second coil in the second step.

Consequently, the power supplied to the first coil during the partial feedback control is controlled such that a ratio between the power supplied to the first coil and the power supplied to the second coil during the complete feedback control is maintained relative to the power supplied to the second coil. Thus, even when the opening for temperature measurement disposed to face the top surface is blocked, the first coil can generate an amount of heat for maintaining the temperature of the top surface at the target value, thereby preventing the temperature control of the crucible during the silicon carbide single crystal growth from becoming unstable.

(Aspect 10)

A method of manufacturing a silicon carbide single crystal, comprising the steps of preparing a crucible having a top surface, a bottom surface opposite to the top surface, and a tubular side surface located between the top surface and the bottom surface, a source material disposed in the crucible on the side close to the bottom surface, a seed crystal disposed in the crucible on the side close to the top surface so as to face the source material, a first resistive heater provided to face the top surface, a second resistive heater provided to surround the side surface, a third resistive heater provided to face the bottom surface, a heat insulator disposed to cover the first resistive heater, the second resistive heater and the third resistive heater, the heat insulator being provided with a first opening in a position facing the top surface, being provided with a second opening in a position facing the side surface, and being provided with a third opening in a position facing the bottom surface, a first pyrometer configured to be able to measure a temperature of the top surface through the first opening, a second pyrometer configured to be able to measure a temperature of the side surface through the second opening, and a third pyrometer configured to be able to measure a temperature of the bottom surface through the third opening, and growing a silicon carbide single crystal on the seed crystal by sublimation of the source material by supplying power to each of the first resistive heater, the second resistive heater and the third resistive heater to heat the crucible, the step of growing a silicon carbide single crystal including a first step in which the powers supplied to the first resistive heater, the second resistive heater and the third resistive heater, respectively, are feedback controlled based on the temperatures of the crucible measured by the first pyrometer, the second pyrometer and the third pyrometer, respectively, and a second step in which the powers supplied to the second resistive heater and the third resistive heater, respectively, are feedback controlled based on the temperatures of the crucible measured by the second pyrometer and the third pyrometer, respectively, and the power supplied to the first resistive heater is controlled to be associated with the power supplied to the second resistive heater, the power supplied to the first resistive heater in the second step being determined by calculation based on a ratio between the power supplied to the first resistive heater and the power supplied to the second resistive heater in the first step, and the power supplied to the second resistive heater in the second step.

In accordance with the method of manufacturing a silicon carbide single crystal according to (Aspect 10) above, during the partial feedback control, the power supplied to the first resistive heater is controlled such that a ratio between the power supplied to the first resistive heater and the power supplied to the second resistive heater during the complete feedback control is maintained relative to the power supplied to the second resistive heater. Thus, even when the opening for temperature measurement disposed to face the top surface is blocked, the first resistive heater can generate an amount of heat for maintaining the temperature of the top surface at the target value, thereby preventing the temperature control of the crucible during the silicon carbide single crystal growth from becoming unstable.

(Aspect 11)

A method of manufacturing a silicon carbide single crystal, comprising the steps of preparing a crucible having a top surface, a bottom surface opposite to the top surface, and a tubular side surface located between the top surface and the bottom surface, a source material disposed in the crucible on the side close to the bottom surface, a seed crystal disposed in the crucible on the side close to the top surface so as to face the source material, a first resistive heater provided to face the top surface, a second resistive heater provided to surround the side surface, a third resistive heater provided to face the bottom surface, a heat insulator disposed to cover the first resistive heater, the second resistive heater and the third resistive heater, the heat insulator being provided with a first opening in a position facing the top surface, being provided with a second opening in a position facing the side surface, and being provided with a third opening in a position facing the bottom surface, a first pyrometer configured to be able to measure a temperature of the top surface through the first opening, a second pyrometer configured to be able to measure a temperature of the side surface through the second opening, and a third pyrometer configured to be able to measure a temperature of the bottom surface through the third opening, and growing a silicon carbide single crystal on the seed crystal by sublimation of the source material by supplying power to each of the first resistive heater, the second resistive heater and the third resistive heater to heat the crucible, the step of growing a silicon carbide single crystal including a first step in which the powers supplied to the first resistive heater, the second resistive heater and the third resistive heater, respectively, are feedback controlled based on the temperatures of the crucible measured by the first pyrometer, the second pyrometer and the third pyrometer, respectively, and a second step in which the powers supplied to the second resistive heater and the third resistive heater, respectively, are feedback controlled based on the temperatures of the crucible measured by the second pyrometer and the third pyrometer, respectively, and the power supplied to the first resistive heater is controlled to be associated with the power supplied to the third resistive heater, the power supplied to the first resistive heater in the second step being determined by calculation based on a ratio between the power supplied to the first resistive heater and the power supplied to the third resistive heater in the first step, and the power supplied to the third resistive heater in the second step.

In accordance with the method of manufacturing a silicon carbide single crystal according to (Aspect 11) above, during the partial feedback control, the power supplied to the first resistive heater is controlled such that a ratio between the power supplied to the first resistive heater and the power supplied to the third resistive heater during the complete feedback control is maintained relative to the power supplied to the third resistive heater. Thus, even when the opening for temperature measurement disposed to face the top surface is blocked, the first resistive heater can generate an amount of heat for maintaining the temperature of the top surface at the target value, thereby preventing the temperature control of the crucible during the silicon carbide single crystal growth from becoming unstable.

It should be understood that the embodiments disclosed herein are illustrative and non-restrictive in every respect. The scope of the present invention is defined by the terms of the claims, and is intended to include any modifications within the scope and meaning equivalent to the terms of the claims.

What is claimed is:

1. A method of manufacturing a silicon carbide single crystal, comprising the step of preparing a device for manufacturing a silicon carbide single crystal,
said device including a first resistive heater which is an annular body in which a crucible can be disposed, a heat insulator disposed to surround the circumference of said first resistive heater, and a chamber that accommodates said first resistive heater and said heat insulator, said heat insulator being provided with a first opening in a position facing said first resistive heater, said chamber being provided with a second opening in communication with said first opening, said first resistive heater having a first slit extending from an upper end surface toward a lower end surface of said annular body and a second slit extending from said lower end surface toward said upper end surface, said first and second slits being alternately arranged along a circumferential direction, said first resistive heater being provided with a third opening penetrating said annular body and being in communication with said first and second openings,
said device further including a first pyrometer disposed outside said chamber, said first pyrometer being configured to be able to measure a temperature of said crucible through said first to third openings,
said method further comprising the steps of:
disposing a source material and a seed crystal facing said source material in said crucible; and
growing a silicon carbide single crystal on said seed crystal by sublimation of said source material.

2. The method of manufacturing a silicon carbide single crystal according to claim 1, wherein
said third opening has a line-symmetrical shape with an axis passing through said first slit or said second slit as a symmetry axis.

3. The method of manufacturing a silicon carbide single crystal according to claim 1, wherein
said device further includes a first terminal having one end electrically connected to one pole of a power supply and the other end connected to said upper end surface or said lower end surface, and a second terminal having one end electrically connected to the other pole of said power supply and the other end connected to said upper end surface or said lower end surface,
said first terminal and said second terminal are disposed in positions facing each other with a central axis of said annular body therebetween, and
said third opening is disposed in a position at least partially overlapping with said other end of said first terminal or said second terminal when viewed from said upper end surface.

4. The method of manufacturing a silicon carbide single crystal according to claim 1, wherein
said step of growing a silicon carbide single crystal on said seed crystal by sublimation of said source material is performed by supplying power to said first resistive heater to heat said crucible,
said step of growing a silicon carbide single crystal includes
a first step in which the power supplied to said first resistive heater is feedback controlled based on the temperature of said crucible measured by said first pyrometer, and
a second step in which the power supplied to said first resistive heater is controlled to be constant power, and
the power supplied to said first resistive heater in said second step is determined by calculation based on the power supplied to said first resistive heater in said first step.

5. The method of manufacturing a silicon carbide single crystal according to claim 4, wherein
said crucible has a top surface, a bottom surface opposite to said top surface, and a tubular side surface located between said top surface and said bottom surface,
said device further includes a second resistive heater provided to face said top surface, and a third resistive heater provided to face said bottom surface,
said first resistive heater is provided to surround said side surface,
said heat insulator is disposed to cover said first resistive heater, said second resistive heater and said third resistive heater,
said heat insulator is provided with a fourth opening in each of a position facing said top surface and a position facing said bottom surface,
said device further includes a second pyrometer configured to be able to measure a temperature of said top surface through said fourth opening, and a third pyrometer configured to be able to measure a temperature of said bottom surface through said fourth opening,
in said first step, the powers supplied to said first resistive heater, said second resistive heater and said third resistive heater, respectively, are feedback controlled based on the temperatures of said crucible measured by said first pyrometer, said second pyrometer and said third pyrometer, respectively,
in said second step, the powers supplied to said first resistive heater and said third resistive heater, respectively, are feedback controlled based on the temperatures of said crucible measured by said first pyrometer and said third pyrometer, respectively, and the power supplied to said second resistive heater is controlled to be constant power, and
the power supplied to said second resistive heater in said second step is determined by calculation based on the power supplied to said second resistive heater in said first step.

6. The method of manufacturing a silicon carbide single crystal according to claim 4, wherein
said crucible has a top surface, a bottom surface opposite to said top surface, and a tubular side surface located between said top surface and said bottom surface,
said device further includes a second resistive heater provided to face said top surface, and a third resistive heater provided to face said bottom surface,
said first resistive heater is provided to surround said side surface,
said heat insulator is disposed to cover said first resistive heater, said second resistive heater and said third resistive heater,
said heat insulator is provided with a fourth opening in each of a position facing said top surface and a position facing said bottom surface,
said device further includes a second pyrometer configured to be able to measure a temperature of said top surface through said fourth opening, and a third pyrometer configured to be able to measure a temperature of said bottom surface through said fourth opening,
in said first step, the powers supplied to said first resistive heater, said second resistive heater and said third resistive heater, respectively, are feedback controlled based on the temperatures of said crucible measured by said first pyrometer, said second pyrometer and said third pyrometer, respectively, and
in said second step, the powers supplied to said second resistive heater and said third resistive heater, respectively, are feedback controlled based on the temperatures of said crucible measured by said second pyrometer and said third pyrometer, respectively, and the power supplied to said first resistive heater is controlled to be constant power.

7. The method of manufacturing a silicon carbide single crystal according to claim 4, wherein
in said step of growing a silicon carbide single crystal, pressure reduction in said crucible is carried out during execution of said first step, and
the power supplied to said first resistive heater in said second step is determined by calculation based on the power supplied to said first resistive heater in said first step after completion of the pressure reduction in said crucible.

8. The method of manufacturing a silicon carbide single crystal according to claim 1, wherein
said crucible has a top surface, a bottom surface opposite to said top surface, and a tubular side surface located between said top surface and said bottom surface,
said source material is disposed in said crucible on the side close to said bottom surface,
said seed crystal is disposed in said crucible on the side close to said top surface so as to face said source material,
said device further includes a second resistive heater for heating said top surface, and a third resistive heater for heating said bottom surface,
said heat insulator is disposed to cover said crucible,
said heat insulator is provided with a fourth opening in each of at least a position facing said top surface and a position facing said bottom surface,
said device further includes a second pyrometer configured to be able to measure a temperature of said top surface through said fourth opening, and a third pyrometer configured to be able to measure a temperature of said bottom surface through said fourth opening,
said step of growing a silicon carbide single crystal on said seed crystal by sublimation of said source material is performed by supplying power to each of said first resistive heater, said second resistive heater and said third resistive heater to heat said crucible,
said step of growing a silicon carbide single crystal includes
a first step in which the powers supplied to said first resistive heater, said second resistive heater and said third resistive heater, respectively, are feedback controlled based on the temperatures of said crucible measured by said first pyrometer, said second pyrometer and said third pyrometer, respectively, and
a second step in which the powers supplied to said first resistive heater and said third resistive heater, respectively, are feedback controlled based on the temperatures of said crucible measured by said first pyrometer and said third pyrometer, respectively, and the power supplied to said second resistive heater is controlled to be associated with the power supplied to said first resistive heater or said third resistive heater, and
the power supplied to said second resistive heater in said second step is determined by calculation based on a ratio between the power supplied to said second resistive heater and the power supplied to said first resistive heater or said third resistive heater in said first step, and the power supplied to said first resistive heater or said third resistive heater in said second step.

9. The method of manufacturing a silicon carbide single crystal according to claim 8, wherein
said heat insulator is disposed to cover said first resistive heater, said second resistive heater and said third resistive heater,
in said second step, the powers supplied to said first resistive heater and said third resistive heater, respectively, are feedback controlled based on the temperatures of said crucible measured by said first pyrometer and said third pyrometer, respectively, and the power supplied to said second resistive heater is controlled to be associated with the power supplied to said first resistive heater, and
the power supplied to said second resistive heater in said second step is determined by calculation based on a ratio between the power supplied to said second resistive heater and the power supplied to said first resistive heater in said first step, and the power supplied to said first resistive heater in said second step.

10. The method of manufacturing a silicon carbide single crystal according to claim 8, wherein
said heat insulator is disposed to cover said first resistive heater, said second resistive heater and said third resistive heater,
in said second step, the powers supplied to said first resistive heater and said third resistive heater, respectively, are feedback controlled based on the temperatures of said crucible measured by said first pyrometer and said third pyrometer, respectively, and the power supplied to said second resistive heater is controlled to be associated with the power supplied to said third resistive heater, and
the power supplied to said second resistive heater in said second step is determined by calculation based on a ratio between the power supplied to said second resistive heater and the power supplied to said third resistive heater in said first step, and the power supplied to said third resistive heater in said second step.

11. The method of manufacturing a silicon carbide single crystal according to claim 8, wherein
in said step of growing a silicon carbide single crystal, pressure reduction in said crucible is carried out during execution of said first step, and
the power supplied to said second resistive heater in said second step is determined by calculation based on a ratio between the power supplied to said second resistive heater and the power supplied to said first resistive heater or said third resistive heater in said first step after completion of the pressure reduction in said crucible, and the power supplied to said first resistive heater or said third resistive heater in said second step.
